(19) United States
(12) Patent Application Publication
(10) Pub. No.: US 2025/0351744 A1
(43) Pub. Date: Nov. 13, 2025

(54) METHOD AND SYSTEM FOR OPTIMISING THE OPERATING TEMPERATURE OF SUPERCONDUCTING QUANTUM PROCESSORS

(71) Applicant: NPL Management Limited, Teddington, Middlesex (GB)

(72) Inventors: Sergey KUBATKIN, Göteborg (SE); Andrey DANILOV, Mölndal (SE); Sebastian DE GRAAF, Teddington, Middlesex (GB); Alexander TZALENCHUK, Teddington, Middlesex (GB); Marijn LUCAS, Egham Surrey (GB); John SAUNDERS, Egham Surrey (GB); Andrew CASEY, Egham Surrey (GB); Lev LEVITIN, Egham Surrey (GB)

(73) Assignee: NPL Management Limited, Teddington, Middlesex (GB)

(21) Appl. No.: 18/867,433

(22) PCT Filed: May 19, 2023
(86) PCT No.: PCT/EP2023/063515

§ 371 Date: Nov. 19, 2024

(30) Foreign Application Priority Data
May 20, 2022 (GB) 2207405.8
Sep. 16, 2022 (GB) 2213659.2

(51) Int. Cl. H10N 60/81; G06N 10/20; G06N 10/40; H01L 23/34

(52) U.S. Cl. CPC H10N 60/81; G06N 10/20; G06N 10/40; H01L 23/34

(57) ABSTRACT

A system for controlling the temperature of a quantum circuit comprises an enclosure comprising enclosure walls made of temperature conductive material; a substrate for holding a quantum circuit; at least one source of cooling fluid; at least one port in the enclosure coupled to at least one source of cooling fluid; a control unit coupled to at least one source of cooling fluid and configured to control or enable the control of supply of cooling fluid to the chamber; wherein the system in use fills the enclosure with cooling fluid so as to cool the quantum circuit. Preferably, at least one source of cooling fluid is a source of ³He, ⁴He or a mixture of the two. The invention provides a method and system for optimising the operating temperatures of superconducting quantum circuits and processors and the environment they operate in.

### TECHNICAL FIELD

The present invention relates to a method and system for thermalising surfaces of solid-state quantum processors, more particularly to a method and system for achieving the optimal operating temperature of solid state quantum devices, circuits and processors. In the preferred embodiments, the method and system taught herein can provide adaptive control of the operating temperature of quantum circuits and processors to seek to attain optimum performance from them and improve quantum coherence. The invention is particularly suited, although not limited to, quantum circuits operated in a superconducting state.

### BACKGROUND OF THE INVENTION

Solid-state (superconducting, semiconducting) quantum circuits (QC) are used to implement quantum bits (qubits, which can be based on superconducting, semiconductor spin, or other solid-state platforms) and such circuits also include low-loss components that are used to interact with the qubits (transmission-lines, conductors, resonators) in various architectures. These solid-state circuits are planar circuits and typically consist of a substrate material (usually 0.1-1 mm thick and commonly made from high-resistivity silicon or sapphire) onto which various circuit layers (typically, metals, dielectrics, superconductors as thin films in one or multiple layers) are deposited and patterned into shape using microfabrication techniques. The substrates may have a surface area of up to several square centimetres.

In more advanced implementations, multiple chips are used, for example one chip consisting of the qubit layer and another chip which is ‘flip-chipped’ on top providing other circuit components (such as resonators, transmission-lines) to solve the connectivity problem of large-scale circuits. These two (or more) ‘flip-chipped’ chips are typically connected using metallic or superconducting links (such as bump-bonds, pads, clamps, wire-bonds around the chip perimeter or far from qubits) to pass signals from one to the other, and a small gap (vacuum) is present between. This gap is present for practical purposes: it is difficult to align chips perfectly with no gap, and the qubits have electric fields which extend out of the plane of the circuit/chip by some distance and these fields must not couple to any lossy dielectric materials introduced.

US-2021/076,530 discloses devices and methods to facilitate employing thermalizing materials in an enclosure for quantum computing devices. The system comprises a quantum computing device disposed within an enclosure. The system also comprises a thermalizing material disposed within the enclosure, which may be superfluid helium.

US-2013/258,595 acknowledged that heat transfer is known to be a concern when scaling up a quantum computer. Some basic superconducting devices may dissipate some energy when switched and may interface in close proximity with the qubits. The disclosure proposes highly conductive thermal vias used to transport hot electrons away from the qubits and into liquid 3He, which has relatively good bulk heat transport properties, such as relatively high thermal conductivity and heat capacity, at milliKelvin temperatures. It is acknowledged that large Kapitza resistance between solids and liquid helium may present an issue getting the heat from the thermal vias to the liquid helium. The disclosure proposes that Kapitza resistance may be minimized by using a porous open-cell metal ‘sponge’ having very high internal surface area per unit volume.

The main aim in the art is to increase the coherence of a quantum circuit. The coherence time is the time within which a quantum circuit can retain quantum information before it is lost. There are numerous sources of de-coherence, that is mechanisms that cause loss of coherence (discussed in further detail below). The art seeks to increase the coherence as the coherence time directly impacts the fidelity of operations. High fidelity is a requirement for achieving fault-tolerant quantum error correction, a prerequisite for universal quantum computing. To be sufficiently coherent, a solid-state quantum circuit needs to operate at low temperatures.

Many of the different sources of de-coherence can be either directly or indirectly associated with excess energy present in the quantum circuit or its environment, and certain de-coherence mechanisms constitute an external source of energy, that, unless efficiently removed from the quantum circuit and its environment, will increase the temperature of the circuit or some other degree of freedom of its environment.

In the present context, we define a “quantum circuit” as the complete chip or assemblies of chips as described. A quantum circuit will typically comprise a substrate(s), dielectrics, metallic and superconducting layers, and so on, patterned into a specific circuit topology to achieve a desired functionality exploiting quantum physics. The aforementioned constituents form a quantum circuit with which it is possible to perform quantum computation, quantum sensing, or in other ways define a quantum device that operates on the fundamental principles of quantum mechanics.

The terms “cooling” or “thermalisation” may or may not include cooling or thermalisation of the quantum states and the thermal population of the quantum states of the device when operated. Furthermore, they may or may not include the cooling or thermalisation of the environment of the quantum circuit to which the quantum circuit couples, meaning the different physical subsystems (or degrees of freedom) present on the quantum circuit chip(s) and other aspects of the cryogenic assembly which may have an associated temperature or temperature dependent property which affects the performance of the quantum circuit. Such subsystems are described in detail below.

### a) Considerations for Quantum Circuit Cooling

Typically, quantum circuits are cooled down inside dilution refrigerators (DR), which achieve a base temperature of around 10 mK, 5 mK being achievable with the best commercially available dilution refrigerators. However, in practical quantum circuit embodiments with a large number of signal lines going down to the quantum circuit base, temperatures well above 10 mK are common, and even of up to 50 or 60 mK depending on the number of lines.

The dilution refrigerator works to cool down the phonon temperature of its lowest temperature stage. The coldest plate is typically a large copper plate, which may be plated in material such as gold (Au) to improve thermal contact and prevent oxidation of the copper. Copper is used because it is a very good thermal conductor at very low temperatures, meaning that any heat generated at one place in the copper plate can efficiently be taken away by the cooling mechanism of the dilution refrigerator, thus maintaining a low temperature.

To cool down the quantum circuit, it needs to be thermally anchored to the cold plate of the dilution refrigerator. Thermal anchoring may typically be achieved as follows:
(i) the chip is placed either directly on a metal base plate (copper being mostly used due to its good thermal properties) or on a printed circuit board (PCB) (specifically, its dielectric or metallised surface) or it is placed with its perimeter on such with an empty space underneath (vacuum) forming a cavity;
(ii) the circuit board (if present) is then placed onto a metal plate (base plate),
(iii) the metal base plate, forming part of an enclosure, is then attached to the dilution refrigerator (DR) cold plate, either directly or via a number of additional metal brackets depending on the configuration.

Achieving fairly good thermalisation up to the point of the quantum circuit enclosure base plate onto which the PCB/QC chip is mounted is reasonably straightforward. The main issue is the thermal link between QC components on the chip and the metal base plate, i.e. thermalisation of the environment of the QC. The circuit layers (superconductors, dielectrics) are thin and very poor thermal conductors. Furthermore, the substrate (typically silicon, sapphire) has a vanishing thermal conductivity at the temperatures at which quantum circuits are operated. Hence, in order to cool down the quantum circuits themselves, a material with better thermal conductivity and low interfacial thermal resistance (Kapitza resistance) towards the quantum circuit materials is needed. Ideally, the empty space (typically vacuum) that is above (and sometimes below) the quantum circuit chip should be filled with some material that can better take away the heat and thermalise the quantum circuit to the temperature of the metal enclosure.

### Electromagnetic Environment and QC Enclosure

At the same time, it is necessary that any material that fills this empty space be insulating so as not to short out any signals, and it must have a very low dielectric loss at microwave frequencies so as not to compromise quantum circuit performance.

If a dielectric material is introduced within the volume occupied by microwave electric fields, the field will mediate the quantum circuit coupling to two-level material defects, which will result in increased loss, noise and decoherence. To avoid this, it is common practice to remove dielectric substrate material on the chip hosting the qubits themselves, in the regions around the qubits and other high-coherence elements where electric fields are large and penetrating into the substrate. Hence it is desired to surround qubit and resonator circuits as much as possible with vacuum (no substrate) in order to improve coherence, which is well known in the art.

It is common to house the quantum circuit within a well-shielded environment, typically formed with superconducting shields, magnetic shields, photon radiation shields, or the like. In practice, this results in a large number of (5 to >10) separate metal components that are attached together in various ways using fasteners. The thermal conductivity between the base plate and the dilution refrigerator (DR) cold plate depends on the number of different metal pieces and their interfaces. For this purpose, gold plating is often used on copper to improve contact between pieces and prevent oxidation, which reduces thermal conductivity through the boundary. Thermal conductivity also depends on the geometry of the pieces, as thermal conductivity is a function of the cross-section and length of the thermal conductor.

To ensure a good electromagnetic environment, the quantum circuit and metal base plate is usually also covered by a base plate cover, such that the quantum circuit and PCB are entirely surrounded by metal (typically copper). This metal enclosure should not be disposed too close to the quantum circuit as it can otherwise distort the electromagnetic modes of the circuit and add additional loss and decoherence. This means that the volume within the enclosure above the quantum circuit is empty (vacuum), which, unfortunately, conducts heat only through radiation which is a very inefficient process.

FIG. 1 shows a typical enclosure for a quantum circuit used in the art (left), and flip-chip configuration (right).

Heat (residual and generated) in the quantum circuit cannot be taken away from the quantum circuit with the same high efficiency as would be the case if it were possible to have an uninterrupted copper link between the quantum circuit surface layer and the cold plate. In fact, for a cold plate temperature of 10 mK, it is common that the quantum circuit itself has an effective temperature well exceeding 50 mK.

As the quantum circuit requires propagation of electrical signals and a well-engineered electromagnetic environment, it cannot be constructed using only materials that are very good thermal conductors (such as copper). Dielectrics, which are very poor thermal conductors at milliKelvin temperatures (vacuum is an ideal dielectric with zero thermal conductivity), are still needed to realise quantum circuits and allow controlled propagation of electrical signals. Furthermore, many signal/control lines in typical quantum circuits are made from superconducting materials which provide low electromagnetic loss, but they also have very poor thermal conductivity compared to a normal metal (such as copper).

The art is as a consequence faced with the necessity of building a quantum circuit from poor thermally conducting materials, and thermalisation in practical embodiments relies on heat conductance through the many interfaces and poor thermal conductors to the cold plate of the refrigerator.

Various attempts have sought to improve the thermalisation in various implementations but such attempts have so far not improved the situation much due to the fundamentally mutually exclusive constraints, namely that for good performance the quantum circuit must be surrounded by low-dissipative dielectric materials that are by definition poor thermal conductors, in order to maintain high coherence and desired functionality.

In a large-scale quantum processing unit (QPU) thermalisation of the circuit would be even more of an issue due to larger dimensions of circuits (chips) that need to be thermalised and due to a substantial number of control signals propagating on chips, resulting in even more heating.

### Cooling the Physical Environment of a Quantum Circuit

The above describes how heat is taken away from the quantum circuit, mainly in the form of phonons, and the physical constraints for operation of such a quantum circuit which limit cooling through phonons from the quantum circuit chip at mK temperatures. The above description also indicates the many objects in immediate proximity of the quantum circuit: the substrate, oxide layers of the superconductor, normal metals, elements of a flip-chip arrangement, and so on. In other words, the quantum circuit couples to an environment with many degrees of freedom, and unwanted energy exchange with this environment compromises the quantum device performance. Removing any excess or undesired energy or excitations from the environment is therefore important.

In practical quantum circuit embodiments it is found that various physical sub-systems and imperfections (defects) present in/on the chip (such as surface or bulk spin defects, quasiparticles, conduction electrons in signal wiring, material defects [typically Two Level System ‘TLS’ defects], and the bath of low energy fluctuators constituting the source of materials related noise and decoherence) have a temperature dependence resulting at degraded quantum device performance as temperature is reduced, with a typical trend that saturates around 50 mK. This is because these sub-systems are poorly thermalised to the dilution refrigerator base temperature, and any minute heat load (for instance from stray radiation, losses in materials, signals propagating, and so on) results in significant overheating of the aforementioned sub-systems with respect to the cryostat base temperature. This has been verified in many experiments on quantum circuits, as well as on superconducting resonators in the quantum regime, where it was demonstrated that both surface spins and the TLS bath in practice cannot be cooled to below about 50 mK.

As an example, FIG. 2 shows a graph depicting the measured and theoretically expected electron spin resonance (ESR) peak intensity as a function of temperature for two coupled surface spin transitions. This data is from a quantum circuit mounted in the typical way of the art, with vacuum surrounding it, and hence poor thermalisation is achieved. Below about 50 mK there is thermal saturation and deviation from the theoretically expected result.

It should be borne in mind that much published research literature available on the temperature dependence of parameters relevant of quantum circuits reports on research conducted 5 or more years ago. At that time, materials and other technologies involved in quantum circuits had not developed to the level they have today. In particular, qubit coherence times were at least an order of magnitude worse than today. Much of the historical research therefore did not investigate properties that are necessarily relevant for state-of-the-art high coherence circuits.

What is now understood in the art is that as coherence increases, parameter fluctuations due to TLS (which also relates to the noise) become more prominent. As a consequence, for state-of-the-art qubits the concept of cooling to lower temperatures is even less desirable on the basis of current knowledge on TLS alone.

### Heat Dissipation in the System

A number of different mechanisms can contribute to the generation of heat in a quantum circuit raising its temperature well above that of the cold plate even when the quantum circuit is passive and not in operation, including:
(i) heat caused by electrical control signals which is dissipated from the circuits. Typical control signals are microwave pulses, constant microwave tones, low frequency (DC) current signals;
(ii) heat from stray photons and thermal radiation from higher temperature stages in the cryostat or thermal radiation from the output amplification chain. Much recent effort has gone into engineering the quantum circuit environment to suppress any high-energy photons reaching the quantum circuit. Techniques include optimising cryostat attenuation and filtering and absorptive materials;
(iii) heat from cosmic particles or ionising radiation absorbed in the quantum circuit or its substrate;
(iv) heat from stray phonons arising from elevated temperatures elsewhere in the cryostat or from other remote high impact events as in (iii);
(v) heat from ortho-para conversion of hydrogen in materials

It is desired to remove this excess heat as efficiently as possible in order to thermalise the quantum circuit to the desired temperature and thereby improve performance.

### Characteristic Temperatures and Temperature Dependencies

A quantum circuit's performance depends on a number of temperature dependent mechanisms that compete. It is not evident from knowledge in the art to conclude that lowering temperature is the solution to improve all these performance metrics, for the following reasons.
(i) Superconductors: Below a certain transition temperature (Tc) some metals lose electrical resistance and repel magnetic fields. The former property translates in low electromagnetic losses, while the latter makes them good magnetic shields. The physical reason for superconductivity is that conducting electrons in metals ‘pair-up’ and these (Cooper) pairs form a ‘condensate’ which behaves as a single whole. At finite temperatures Cooper pairs coexist with quasiparticles which are broken Cooper-pairs (single electrons).
(ii) Quasiparticles: These are a property of the superconducting material. Quasiparticles contribute to electromagnetic loss at high frequencies and cause parity fluctuations in quantum circuits, which mechanisms lead to noise and decoherence. Close to the superconducting transition temperature (Tc), the number of quasiparticles is the largest and decays exponentially for T<Tc. In typical superconductors used for quantum circuits (such as Aluminium, Niobium, Niobium Nitride), the temperature of the quantum circuit is typically at least 20 times below the superconducting transition temperature, meaning that the residual quasiparticle density should be essentially zero (<exp(−20)=2e−9). Yet it has been observed that the number of quasiparticles present saturates below 100 mK at a value significantly higher.

The reasons for this are currently a topic of debate in the art. An origin is believed to be a constant re-supply of quasiparticles through Cooper-pair breaking events associated with high energy impacts (cosmic particles or ionising radiation), in combination with the very slow quasiparticle recombination-time (two quasiparticles form a Cooper pair) in the limit of few quasiparticles. Other sources of high energy that generate pair breaking events are also possible, and in this context it may be desirable to reduce the temperature further to understand how that influences the number of quasiparticles and improve phonon thermalisation. The art is currently seeking to understand and eliminate this source. It is theoretically feasible to remove sources of ionising radiation next to a quantum circuit by using materials very clean of radioactive isotopes. It is also feasible, but impractical, to shield the quantum circuit against high-energy cosmic rays by operating it deep underground. Another way to reduce, but not eliminate, the impact of high-energy events and quasiparticles demonstrated in the art, is to create quasiparticle traps in the superconducting layer of the quantum circuit by engineering zones away from quantum circuit where quasiparticles would predominantly get trapped, preventing their propagation to the relevant quantum circuit elements.

From current knowledge, in the context of quasiparticles, there is therefore no reason to believe that additional cooling of a quantum circuit would reduce the number of residual quasiparticles.
(iii) Residual qubit thermal population: Superconducting qubits operate typically only using two energy levels with typical separation (splitting) equivalent to frequency in the range 1-10 GHz or temperature in the range of 50-400 mK. In order to ensure reliable control of the qubit, no thermal (accidental) population of the upper level is desired. This thermal population follows Boltzmann statistics, meaning lower temperature of the qubit environment results in lower thermal population. Experiments using superconducting qubits typically show the expected thermal population down to about T=50 mK, where it saturates at an excess value of a few fractions of a percent. This is a major problem as it limits qubit operation fidelity. In this context extensive filtering of input signal lines is required to reduce the amount of stray photons coupling to the device, and the electromagnetic environment should be well shielded from thermal photons. Cooling the quantum circuit and its environment from which there may be many different sources of thermal photons is therefore beneficial. In this aspect it would be desired in the art to thermalise to the lowest possible temperature.
(iv) Flux noise: Magnetic impurities and surface magnetic moments result in magnetic (flux) noise which also limits coherence of a quantum circuit. It has been observed that the flux noise in a quantum circuit increases as temperature decreases (until the typical saturation at 50-100 mK).
(V) Critical current fluctuations: These fluctuations are believed to arise from defects in the Josephson junction barrier. Little is known about the temperature dependence below 90 mK, but above this temperature the critical current noise is shown to be proportional to T².
(vi) Two-level system (TLS) material defects: These are believed to reside mainly in the dielectrics surrounding a quantum computer, including substrate and oxide layers of superconductor, although some special type of TLS may reside in the superconductor or Josephson junction barrier itself. In simple terms, TLS defects are described as an atomic scale defect which jumps between two positions. Importantly, this defect possesses electric charge resulting in an electric dipole or quadrupole moment which can couple to the quantum circuits. The ‘jumps’ are responsible for noise which compromises quantum circuits performance. TLS also interact among themselves. It is known in the art that going to lower temperatures increases the noise and decoherence caused by a TLS. Experimentally it has been shown that in the regime dominated by TLS the noise increases until saturated at about 50 mK. This is in the same temperature range where other properties of quantum circuits appear to saturate. TLS defects also lead to parameter fluctuations, which is a major problem in the coordinated control of large numbers of qubits in a quantum circuit.

In this regard, it therefore runs contrary to knowledge and understanding in the art to seek to go to lower temperatures. The art has focused on efforts to understand the physics and chemistry of TLS defects, identify their location and eliminate or passivate them as much as possible. While this appears a viable direction, it has so far resulted in limited progress.

The general understanding in the art is that such TLS defects are typically saturated at high temperatures. However, as the material is cooled, these additional degrees of freedom become available and can dominate the low temperature properties.

Taken together, all these mechanisms are contradictory in terms of what the optimal temperature for operation is. The art has settled for a long time to operate a quantum circuit at the readily achievable temperature of about 50 mK (using the base temperature of the dilution refrigerator of 10 mK). This can be achieved readily by mounting the quantum circuit on the mixing chamber plate of a dilution refrigerator and constitutes a best effort compromise between the above-described competing mechanisms. However, this still does not resolve the need to improve the coherence of quantum circuits.

### Cooling Electrical Circuits to Microkelvin Temperatures

Temperatures below typical dilution refrigerator (DR) temperatures (the best DR temperatures that can be achieved are 5 mK to 10 mK, or more) can be obtained with adiabatic nuclear demagnetisation refrigeration (ANDR). The latter technique allows to reach temperatures in the 100 μK range and lower. Importantly, in this temperature range the problem of cooling a quantum circuit and its environment is even more severe than in the milliKelvin temperature range. With adiabatic nuclear demagnetisation refrigeration, a remote nuclear stage (NS), typically also a copper plate, is thermally connected to a paramagnetic material (e.g. copper, PrNi5, . . . ) that provides additional cooling by the process of adiabatic nuclear demagnetisation. The nuclear stage is connected to the mixing chamber plate of a dilution refrigerator through a heat switch. The quantum circuit enclosure with the quantum circuit mounted inside are thermalised to the nuclear stage directly or to a plate to which the nuclear stage is thermally connected.

As far as the quantum circuit chip mount is concerned, there is no difference between a dilution refrigerator and an adiabatic nuclear demagnetisation refrigerator—it is still mounted in its enclosure on a copper base plate, but this time the base plate is the nuclear stage.

The art has focused so far on developing techniques for cooling down electronic systems to ultra-low temperatures, seeking to achieve electron temperatures in devices that are as low as possible. It is not evident in the art that these techniques will also cool down TLS and other subsystems relevant for quantum circuits. Work has focused so far on cooling low frequency electronic devices—that is cooling phonons or conduction electrons in for example semiconductors, metals or quantum Hall devices and two-dimensional electron gases, or single charge devices including Coulomb blockade thermometers commonly used to determine the temperature at sub mK temperatures. The techniques applied so far in the art for cooling the aforementioned type of devices are of less relevance for quantum circuits, and it is not certain in the art that these techniques would also be able to cool down subsystems relevant for quantum circuits.

To measure temperatures at sub-mK, two main techniques are used that effectively measure electron temperature, which is not the temperature of all subsystems in devices. Typically, these thermometers are placed somewhere on the cold plate of the cryostat. The two most common techniques are Coulomb blockade thermometry (CBT) and (current-sensing) resistance noise thermometry. In the disclosure that follows the latter technique is used to measure the temperature of the cold plate of the nuclear stage.

There is therefore no guidance in the art at to what the optimal operation temperature of a quantum circuit may be, as there are competing mechanisms that may contribute differently from quantum circuit to quantum circuit, and it is not clear from the present knowledge in the art that cooling of the various sub-systems relevant for quantum circuits is even achievable. There is therefore no indication in the art that there is any overall benefit in seeking to go to lower temperatures than what is currently readily achievable (T˜50 mK).

### SUMMARY OF THE PRESENT INVENTION

The preferred embodiments of the present invention seek to provide a method and system for introducing a cold quantum fluid and immersing the quantum circuit in this fluid. By controlling the temperature of the quantum fluid, the temperature of the quantum circuit and its environment (in the form of many different physical sub-systems with their own specific temperature dependences that affect the performance of the quantum circuit) can also be controlled.

More particularly the present invention provides a method and system for optimising the operating temperatures of superconducting quantum circuits and processors and the environment they operate in. In the preferred embodiments, the method and system taught herein can provide adaptive control of the operating temperature of superconducting quantum processors circuits and to ensure optimum operation and improve coherence.

The disclosure that follows teaches methods and systems by which a quantum circuit can be cooled much more efficiently using for instance immersion in liquid ³He, in the taught environment. The preferred method and system can also allow an operator of the quantum circuit (whether human or machine) to choose the optimal or otherwise desired operational temperature of the surrounding fluid (thereby also changing the temperature of the quantum circuit and its environment) as determined by the application across a much broader range than is otherwise achievable, as well as to optimise performance against all different coherence limiting mechanisms at play. The method and system taught herein can also accommodate future developments in materials science which may, for example, lead to much reduced TLS-induced decoherence and which could significantly shift the optimal working temperature well below what is currently used.

As is demonstrated herein, ³He is a very efficient low-loss cooling medium, and there is taught a method and system as to how to implement the immersion of a quantum circuit operated in a commercial cryogen-free dilution refrigerator in liquid ³He. The preferred embodiments are able to achieve significantly improved thermalisation of surface spins and TLS subsystems, main contributors to decoherence. As explained in detail below, in the preferred embodiments taught herein, the much improved coupling of the TLS bath to ³He provides much improved thermalisation of the TLS and the TLS bath relaxation rate can be increase over one thousandfold. The inventors know of no earlier experiment or study that has successfully demonstrated cooling of any or all of these physical subsystems down to temperatures below 40-50 mK. While some studies has reported circuits operated at the nominal temperature of 10 mK, the base temperature as seen on the thermometer on the dilution refrigerators cold plate, in all of these studies the cold plate temperature do not represent the temperature of the quantum circuit and its environment.

According to an aspect of the present invention, there is provided a system for controlling the temperature of a quantum circuit to an operating temperature below 100 mK, the system including:
an enclosure comprising enclosure walls made of thermally conductive material;
a volume of porous media made of thermally conductive material disposed in the enclosure and thermally coupled to at least a part of the enclosure walls;
a substrate for holding a quantum circuit;
at least one source of cooling fluid;
at least one port in the enclosure directly coupled to the at least one source of cooling fluid;
a control unit coupled to the at least one source of cooling fluid for filling the enclosure with cooling fluid to cool the quantum circuit and/or its environment, wherein the control unit is configured to control the supply of cooling fluid to the chamber so as to control a degree of cooling provided by the thermalising fluid in the enclosure and thereby the amount of cooling provided to the quantum circuit.

The term “cooling fluid” is used herein to represent a fluid, whether gas or liquid, able to transfer heat, that is that can act to cool.

Preferably, at least one source of cooling fluid is a source of ³He, ⁴He or a mixture of the two. More preferably, at least one source of cooling fluid is a source of liquid ³He.

Advantageously, the volume of porous media is a sintered material.

The volume of porous media is preferably separated from the quantum circuit so as to provide a volume of thermalising fluid between the quantum circuit and the porous media. In the preferred embodiments, the volume of porous media is located with respect to the quantum circuit such that it is disposed at a distance at which electromagnetic fields from the quantum circuit entering the volume of porous media are small enough as to not reduce the performance of the quantum circuit.

There is preferably provided a screening element disposed between the volume of porous material and the quantum circuit. The screening element is advantageously made of at least one of a conductive metallic and a superconducting material. It may comprise a layer of superconducting material disposed over a layer of metallic material.

In some preferred embodiments, the porous material comprises textured or porous internal surfaces of the enclosure walls.

The porous material may comprise heat conductive sintered powder or particles.

The system preferably comprises a capillary coupling the source of cooling fluid to the enclosure, wherein in use the capillary is continuously filled with thermalising fluid during operation of the system. The capillary may be a valveless coupling between the enclosure and control unit.

A filter may be provided, comprising a housing of conductive material, having one end coupled to an inlet capillary and an opposite end coupled to the or a capillary coupled to the enclosure, wherein the housing provides a chamber filled with a sinter filtering element, the filter being operable to reduce or prevent high frequency noise from entering the enclosure through the filling capillary and improve thermalisation of cooling fluid entering the enclosure.

The system can comprise first and second sources of cooling fluid, the first source being a source of ³He and the second source being a source of ⁴He, wherein the control unit is configured to operate or to enable operation of the first and second sources to supply cooling fluid sequentially or simultaneously. In these implementations, the system can deposit layers of cooling fluid onto the quantum circuit, which layers in practice are able to be in solid form. Layering in this manner can optimise the coupling of the cooling liquid to the different subsystems in the quantum circuit and its environment.

The control unit is preferably operable to control the amount and/or pressure of cooling fluid in the enclosure.

Advantageously, the control unit is configured to control the supply of thermalising fluid and pressure to generate one or more layers of thermalising material onto the quantum circuit.

In some embodiments, the control unit is configured to template separate layers of solid thermalising material at the surface of the quantum circuit, said layers being of the same or different thermalising material.

Advantageously, the control unit is operable to control the amount and/or pressure of cooling fluid in the enclosure.

The system preferably comprises one or more sensors configured to measure at least one parameter of the quantum circuit.

The system may comprise at least one temperature sensor configured to obtain a measure of the operating temperature of the quantum circuit, wherein the control unit is configured to control or enable the control of the source of cooling fluid on the basis of the temperature measure.

Advantageously, the control unit is operable to control the amount and/or pressure of cooling fluid in the enclosure on the basis of the measured parameter.

There are preferably provided one or more sensors configured to measure one or more of: noise, decoherence, thermal excitation probability of qubit states, phonons, quasiparticle density, losses, temperature-dependent superconductor properties.

There may be provided one or more sensors configured to measure one or more of: qubit relaxation or dephasing times, single or multi qubit gate fidelity, error rate of a logic qubit, algorithm fidelity, quantum gate operation fidelity.

The control unit may be configured to control or enable the control of the amount and/or pressure of cooling fluid in the enclosure on the basis of measured or expected power dissipation in the quantum circuit.

In some embodiments the enclosure may be configured to hold a plurality of quantum circuits in a plurality of sub-enclosures, wherein the temperature in each sub-enclosure is controllable, preferably individually controllable.

Advantageously, at least a part of the enclosure internal walls are connected to a volume of porous thermally conductive material for the purpose of achieving thermalisation of the liquid to the metal of the enclosure, and therefore to achieve thermalisation to the lowest temperature stage of the cryogenic refrigerator. Once the liquid has been well-thermalised to the refrigerator temperature it is then able to provide cooling to the quantum circuit. The internal walls of the enclosure may have textured or porous internal surfaces comprising heat conductive sintered powder or particles. In some embodiments, the enclosure may be filled with heat conductive sintered powder or particles.

The control unit may be configured to control or enable the control of temperature on the basis of determined performance of the quantum circuit. This may be on the basis of determined coherence of the quantum circuit.

The control unit can be configured to control the amount and/or pressure of cooling fluid in the enclosure on the basis of measured or expected power dissipation in the quantum circuit.

In some embodiments, the enclosure is configured to hold a plurality of quantum circuits in a plurality of sub-enclosures, wherein the temperature in each sub-enclosure is controllable.

The system may include an adsorption pump operable to adsorb an amount of cooling fluid for the purpose transferring cooling liquid (in gaseous form) between the gas handling system and the fill line and enclosure, thereby providing better and wider range of control of the amount and pressure of cooling liquid in the enclosure. In a preferred implementation the adsorption pump is used to achieve a pressure in the fill line significantly above that of the low-pressure side of the gas handling system acting as the source and storage of cooling liquid (in gaseous form). In a preferred implementation the low-pressure side of the gas handling system is operated below atmospheric pressure. In some implementations it may be advantageous to operate the system with a pressure of the cooling liquid significantly above atmospheric pressure.

The system may include a ballast volume connected to the or a fill line at room temperature with the purpose of stabilising the pressure of the liquid in the fill line and enclosure, thereby stabilising the physical and dielectric properties of the cooling liquid such as to improve stability of quantum circuit parameters. For example, it helps protect the quantum circuit from fluctuations induced by temperature fluctuations of different temperature stages of the refrigerator when the fill line is operated in a valveless fashion by continuously being filled. In a preferred implementation the volume of the ballast volume is much larger than the combined volume of the fill line and internal enclosure volume.

According to another aspect of the present invention, there is provided a method of controlling the temperature of a quantum circuit to an operating temperature below 100 mK, in a system including:
an enclosure comprising enclosure walls made of temperature conductive material;
a volume of porous media made of thermally conductive material disposed in the enclosure and thermally coupled to at least a part of the enclosure walls;
a substrate for holding a quantum circuit in the enclosure;
at least one source of cooling fluid;
at least one port in the enclosure directly coupled to the source of cooling fluid; and
a control unit coupled to the at least one source of cooling fluid;
the method comprising the steps of operating the control unit to fill the enclosure with cooling fluid to cool the quantum circuit and/or its environment, and to control the supply of cooling fluid to the chamber so as to control the amount of cooling provided to the quantum circuit and thereby a degree of cooling provided by the thermalising fluid in the enclosure, said control permitting to tune the performance of the quantum circuit.

Preferably, the method comprises providing as the cooling fluid ³He (Helium with isotope number 3), ⁴He (Helium with isotope number 4) or a combination or a mixture of the two. In some embodiments, the system and method taught herein are configured to add first an amount of one cooling fluid, for example ⁴He, which has the effect of creating a layer of the first cooling material on the surfaces of the circuit (substrate). Subsequently, a second cooling fluid (such as ³He) is fed into the chamber, which has the effect of creating layers of cooling compound on the surfaces of the circuit to be cooled. This layering technique can be used to control the coupling between the quantum circuit's environment and physical subsystems towards the cooling liquid, as a result of which the thermal characteristics of the cooling medium and the controlled cooling of the circuit can be optimised. In these embodiments, multiple thermal materials are provided in layers, although in other embodiments the thermal materials can be mixed together into a single layer (or one layer of a multi-layered thermal control structure).

In practice, the aim of this feature is to form on the substrate (circuit) one or more solid layers which optimise thermal coupling. Typically, the layer or layers will be very thin, of the order of one to a few atoms thick. While preferably the or each layer is a complete layer across the surface of the substrate (circuit), it is not excluded that in some cases the or at least one of the layers may be a partial layer, that is does not form a complete covering over the entire surface of the substrate (circuit).

The principle of these embodiments is to form a solid layer over the substrate (circuit) that is of a different material or composition than the bulk cooling material in the chamber. In one practical embodiment, first a thin layer of ⁴He is applied over the substrate and then the chamber is filled up with bulk ³He. In other embodiments one or more layers of ⁴He or ³He are applied prior to the chamber being is filled with ³He, ⁴He or a mixture of the two.

More preferably, the method comprises providing as the cooling fluid liquid ³He.

The method advantageously controls the amount and/or pressure of cooling fluid in the enclosure.

The method may comprise the step of measuring at least one parameter of the quantum circuit. The method may, for example, comprise the step of measuring the operating temperature of the quantum circuit, and controlling the supply of cooling fluid on the basis of the temperature measure. It may also comprise the step of controlling the amount and/or pressure of cooling fluid in the enclosure on the basis of the measured parameter.

Advantageously, the method comprises the step of sensing one or more of: noise, decoherence, thermal excitation probability of qubit states, phonons, quasiparticle density, losses, temperature-dependent superconductor properties. It may also or alternatively comprise the step of measuring one or more of: qubit relaxation or dephasing times, single or multi qubit gate fidelity, error rate of a logic qubit, algorithm fidelity, quantum gate operation fidelity.

The method may comprise the step of controlling the amount and/or pressure of cooling fluid in the enclosure on the basis of measured or expected power dissipation in the quantum circuit.

In some embodiments, the method comprises the step of holding a plurality of quantum circuits in a plurality of sub-enclosures, and controlling the temperature in each sub-enclosure individually.

Preferably, the enclosure walls have textured or porous internal surfaces. They may have textured or porous internal surfaces comprising heat conductive sintered powder or particles. The enclosure may be filled with heat conductive sintered powder or particles.

The method may include the step of controlling temperature on the basis of determined performance of the quantum circuit, for example on the basis of determined coherence of the quantum circuit.

In general terms, the teachings herein preferably use liquid ³He (Helium with isotope number 3) as a cooling medium in a technical solution to implement an immersion cell suitable for quantum circuits operated in dilution refrigerators. While the results indicated below relate to ³He in its ‘normal’ fluid (non-superfluid) state, as opposed to the superfluid state (below 0.9 mK at saturated vapour pressure), it is believed that cooling is also efficient, but less so, with ³He in the superfluid state.

It is believed that in the method and system taught herein, in addition to cooling, ³He affects the circuit and its environment in various ways that may lead to improved coherence of the quantum circuit.

The teachings herein demonstrate that ³He can be a very good cooling medium with low dielectric loss and teach how to implement the immersion of a quantum circuit operated in a commercial cryogen-free dilution refrigerator in liquid ³He. Significantly improved thermalisation of surface spin and TLS subsystems can be achieved. It allows effective control of quantum circuit and environment temperature from 5 mK to >50 mK when mounted in a dilution refrigerator, and from <1 mK to >50 mK when mounted on a nuclear adiabatic demagnetisation refrigerator stage that offers additional cooling.

In place of ³He, ⁴He (Helium with isotope number 4) can also be beneficial, either used in place of ³He or in combination with ³He, as described herein.

The preferred embodiments of the invention seek to provide a method and system of adaptive cooling, whereby the optimal temperature of the quantum circuit can be obtained, whatever the optimal temperature might be. Such adaptive cooling may be either static or dynamic, in which one or more performance metrics relevant for the quantum circuit are optimised against temperature. Different quantum circuits may have different optimal temperatures depending on the specific influence of various physical mechanisms causing degraded performance on the key aspects of the operation of the quantum circuit and its specific application. Different quantum circuits that otherwise have the same application or functionality may still have different optimal temperatures depending on the way they have been implemented.

Suitable performance metrics include, but are not limited to, properties of directly measured physical systems such as, used singularly or in combination:
Noise from charged material defects or paramagnetic impurities (charge noise or flux noise)
Decoherence
Thermal excitation probability of qubit states
Population density of thermally excited phonons
Quasiparticle density
Losses
Temperature-dependent superconductor properties

Other suitable performance metrics are parameters that can be inferred from the operation of the device, and include one or more of:
Qubit relaxation or dephasing times (key basic metric)
Single- or multi-qubit gate fidelity (key metric for quantum processor)
Error rate of a logic qubit (constructed from multiple physical qubits)
Fidelity of a particular quantum gate operation
Fidelity of a particular algorithm, or class of algorithms or sub-algorithms, run on the quantum processing unit (QPU)
As to minimise the need for repeated re-calibration of the QPU to achieve optimal performance
Temporal stability of one or several device specific parameters or performance metrics
The sensitivity, stability, or signal-to-noise ratio of a quantum circuit operated as a quantum sensor (e.g. magnetometer, charge sensor, single photon detector, and the like)

Any combination of parameters, such as but not limited to the ones listed, could also be used in the evaluation of the optimal temperature.

In certain circumstances it might also be desirable to vary the temperature of the quantum circuit during operation, or the cooling power provided by the ³He cooling system. For example, while performing less resource intensive calculations in a quantum processing unit only parts of the unit may be utilised and thus heat dissipated is low. In order to sustain the optimal temperature of the circuit, the adaptive cooling system could be configured to a reduced cooling power. On the other hand, when conducting resource intensive calculations utilising the full quantum processing unit, more heat is dissipated and the cooling power of the adaptive cooling system can be increased to maintain the same, low, optimal operation temperature.

To implement such adaptive cooling, a feedback loop can be constructed: a relevant quantity is measured and deviation from optimal temperature is determined by a suitable algorithm or by user evaluation. The algorithm or user determines the new target temperature, which is realised by increasing or decreasing the heating of power applied by a (resistive) heater to the cryostat cold plate, which is thermally linked to the quantum circuit as described above.

The same housing and adaptive cooling system may also be used in a configuration where multiple quantum circuits are integrated within the same housing. Examples of this is a quantum processing unit plus separate parametric amplifiers connected in series with the output (readout) microwave lines of the quantum processing unit. This allows amplifiers to be disposed as close as possible to the quantum processing unit in order to minimise signal loss between quantum processing unit and the amplifier. With such an arrangement, the quantum processing unit can be less affected by the additional heat dissipated by the amplifiers. A microwave filter through which the cooling medium can flow (described below) can also provide a convenient way to separate two microwave environments sharing the same cooling housing (for instance using a sintered metal powder volume in-between).

In other implementations the same adaptive cooling system and housing can be made to form part of the dilution refrigerator itself, the cell containing the cooling liquid and quantum circuit is integrated with the mixing chamber of a dilution refrigerator.

Other aspects and features of the invention are described below, as will be apparent to the person skilled in the art from the teachings that follow.

### BRIEF DESCRIPTION OF THE DRAWINGS

Embodiments of the present invention are described below, by way of example only, with reference to the accompanying drawings, in which:

FIG. 1 is a schematic diagram showing a typical enclosure for a quantum circuit and a flip-chip configuration thereof;

FIG. 2 is a graph showing the temperature dependence of paramagnetic surface spins in a poorly thermalised quantum circuit surrounded by vacuum.

FIG. 3 is a schematic diagram of an embodiment of adaptive temperature control system;

FIG. 4 is a schematic diagram of a preferred embodiment of ³He gas handling system;

FIG. 5 is a schematic diagram of a preferred embodiment of RF filter for ³He fill line;

FIG. 6 is a schematic diagram of an embodiment of quantum circuit measurement installation, here particularly a microwave installation;

FIG. 7 is a schematic diagram of an embodiment of helium immersion cell;

FIG. 8 is a graph depicting resonator frequency shift as ³He is introduced into the quantum circuit cell;

FIGS. 9A and 9B are graphs depicting in situ electron spin resonance spectra arising from surface spins coupling magnetically to the resonator;

FIG. 10 is a graph showing superconducting resonator frequency spectral noise density normalised to the resonance frequency (6.4 GHZ) at 0.1 Hz versus the temperature of the cold plate of the nuclear demagnetisation stage used to achieve temperatures well below 1 mK;

FIG. 11 is a graph showing power dependence of noise at two temperatures;

FIG. 12 is a graph showing resonator noise magnitude as a function of temperature for two cases: (a) some ³He present in the cell resulting in a thin layer (few nm) on the surface of the device, and (b) a cell fully filled with ³He;

FIG. 13 is a schematic diagram of a microwave filter that may be used in the preferred embodiments of the present invention;

FIG. 14 shows the change in quality factor versus average photon number in a resonator with and without ³He in the cell;

FIG. 15 shows the effect of applying pressure to the ³He in the cell; and

FIG. 16 is a schematic diagram of a preferred embodiment of apparatus demonstrating a mechanism for separating the volume of sinter from the quantum circuit elements while still providing for enhanced heat transfer from the thermalising fluid and specifically a volume of thermalising fluid in contact with the quantum circuit components.

### DESCRIPTION OF THE PREFERRED EMBODIMENTS

The teachings below are directed to a method and system (apparatus) for providing additional cooling to a quantum circuit (QC) and quantum processing unit (QPU) and their environments in order to ensure operation thereof at reduced temperatures below around 50 mK and preferably in the region of 10 mK or so. The method and system also preferably adaptively control temperature of the quantum circuit or quantum processing unit in order to ensure optimum, or near optimum or desired, operation thereof. The controlled temperature need not be a minimum temperature but is preferably determined by measuring one or more operating parameters of the quantum circuit or processor and ensure the measured parameter or parameters are at a deemed optimum or preferred level. Such adaptive control can be effected on a periodic basis, for instance on start-up, or on a continuous basis during operation of the circuit or processing unit.

The preferred embodiments make use of an enclosure made of a highly thermally conductive material which is thermally connected to the lowest temperature stage base plate of the cryostat in which the embodiment is housed. The enclosure which is flooded (or filled) with a low temperature fluid, ³He being preferred, the enclosure comprising temperature transfer enhancement features, providing a large surface area between the conductive walls of the enclosure and the contained fluid, for optimising the heat transfer from the fluid to the enclosure and cryostat. The quantum circuit or unit is held within the enclosure and subjected to the low temperature environment directly through the low temperature fluid. The system comprises a control unit configured to control or enable the control of the temperature of the system (enclosure and liquid) upon the basis of measured circuit or processing unit parameter(s) or generated heat energy or on the basis of deemed operating temperature or heat generating operation. The resultant effect is that the quantum circuit(s) can be operated at lower temperatures than previously achieved to optimise the functionality of the circuit(s). Additionally, the adaptive nature of the system and method can ensure that even when operation of a circuit would normally cause a rise in the actual operation temperature of the quantum circuit, as occurs in prior art systems, the system and method taught herein can maintain the actual operating temperature of the circuit(s) at the deemed optimum or other preferred temperature.

It is to be understood that the description that follows discloses preferred embodiments only and that the skilled person will be able to devise other embodiments making use of the teachings herein.

The main components of the described embodiment could be considered as being formed of three parts:
(1) a gas handling system (GHS),
(2) a control signal system for the quantum circuit and
(3) a cell or enclosure for the quantum circuit.

It will be appreciated that the system will also include a controller for controlling the temperature of the fluid, comprising for instance heating of the plate by a resistive heater.

The system aims at immersing a micro/nano-fabricated quantum device into what could be described as a quantum bath, containing preferably liquid ³He, ⁴He or a mixture of the two. Provided below are qualitative and quantitative assessments of each part, or element, of the setup.

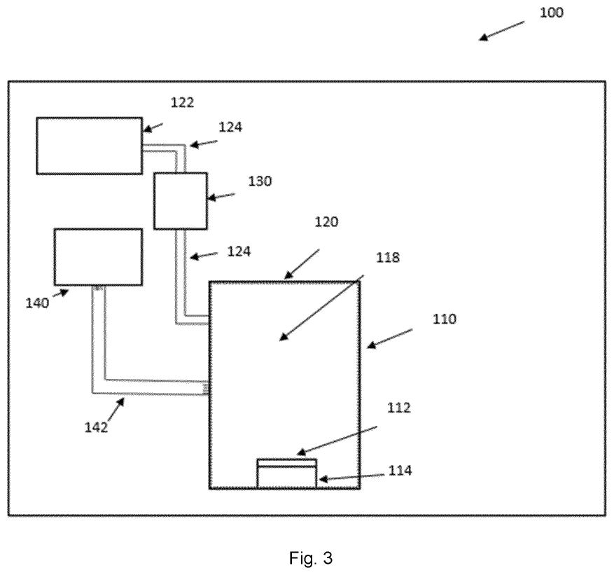

A schematic diagram of the apparatus, or system, is shown in FIG. 3. The apparatus 100 comprises an enclosure or chamber 110 preferably made of or internally lined with a highly heat conductive material such as copper (or gold coated copper). The internal walls 118 of the enclosure are preferably configured to have a much larger surface area than the area of the walls themselves, in this example by sintering parts of the internal walls with heat conductive particulate material, as described in further detail below. Increasing the effective surface area of the internal walls and adjusting the packing ratio of the sinter is done to optimise heat transfer from the walls to the interior of the enclosure, specifically to a fluid within the chamber 110.

As a result of the acoustic mismatch between liquid He and bulk metal, thermal resistance at solid metal/He interfaces is very high, hence making thermalisation of liquid He poor. To reduce the thermal resistance at the interface, one can increase the contact surface between the fluid and the solid with sinter. The other reason why sinter reduces the thermal boundary resistance at liquid ³He/solid metal interfaces is because of its porous structure. When the packing ratio is optimised, the particles composing the sinter bridge with each other to form long structures intertwined with long fluid channels. These sintered structures are more favourable to propagate low frequency phonons present in ³He, thus improving the heat transfer from the fluid to the solid. Therefore the sintered structure and the size of the sinter particles that are used are vital elements for facilitating the thermalisation of the fluid and hence also for in turn thermalising the quantum circuit.

Disposed within the chamber 110 is a quantum circuit or processor unit 112 supported on a substrate 114, which could be a PCB or directly form part of the enclosure wall or some other material. This substrate preferably mediates cooling by having a low temperature of less than 50 mK, preferably to the much lower temperatures disclosed herein (10 mK or less), close to the temperature of the refrigerator used.

The apparatus also includes a source 122 of fluid, in the preferred embodiments ³He, ⁴He or a mixture of the two, in liquid or gas form. The source of fluid is coupled via a pipe or other conduit 124 through a fluid control unit, or valve, 130, used for controlling the amount of fluid supplied into the chamber 110.

There is also provided a sensor unit 140, connected to the chamber 110, the quantum circuit 112 and any other element of the apparatus as appropriate, via one or more sensor connectors 142. The sensor unit 140 may include one or more sensors designed to measure one or more parameters of the apparatus 100, as described in further detail below, including for example, temperature of fluid within the chamber 110, fluid pressure within the chamber 110, operating temperature of the quantum circuit or quantum processing unit 112, power usage of the quantum circuit or processing unit 112, and so on. The unit 140 can make use of sensors known or apparent to the skilled person in the art, so these are not described in further detail herein.

The apparatus will typically also include a processing unit to control the system, which may be a part of the source 122, of the sensor unit 140 or a separate unit. The processing system will typically also comprise a temperature control system.

The gas handling system is used to store, in this embodiment, ³He gas at room temperature. It comprises a gas transfer unit 130 configured to transfer ³He gas from the storage into the chamber 110, and which is able to adjust the amount of gas transferred into the chamber, adjust the pressure of the ³He fluid inside the chamber, and finally remove the ³He fluid from the chamber. The gas transfer unit is described in further detail below.

The apparatus also comprises a control signal system, described in further detail below, and which may form part of the cell 110. In the present embodiment it is used to carry microwave signals to the cell, return and amplify the signal from the cell, minimise the perturbations from the outer environment to the cell. The control signal system may contain any number of input and output signal lines that can be supporting either microwave signals, typically in the range 1-10 GHZ, or low frequency <1 GHz to 0 Hz signals used to control or read out the quantum circuit, the specific requirements being determined by the specific implementation of the quantum circuit.

The control signal system is preferably designed to be compatible with measurements performed on an adiabatic nuclear demagnetisation stage or a dilution refrigerator. The cell or chamber 110 contains the quantum device 112 and the cooling fluid (helium), provides electrical and mechanical shielding to the quantum device, connects the quantum device to the control signal system, and provides appropriate conditions for microwave measurements of the quantum device.

Typically, a dilution refrigerator is used for cooling the quantum circuit, but alternatives exist to achieve even lower temperatures. Attaching a nuclear demagnetisation unit onto the dilution refrigerator base plate provides an extra stage of cooling using the physics of adiabatic nuclear demagnetisation. This results in another plate (nuclear stage, NS) that is similar to a dilution refrigerator cold plate (typically gold plated copper) in which a thermodynamical temperature as low as 100 micro-kelvin or less can be achieved. Techniques for cooling electronic devices to very low temperatures are known.

### The Gas Handling System

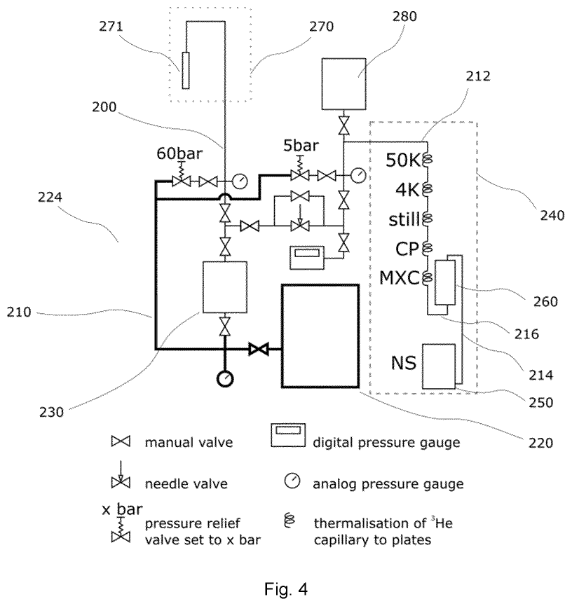

The gas handling system of the preferred embodiment is shown in schematic form in FIG. 4 and comprises a high-pressure line or tube (thin black line) 200 and a low-pressure line (thick black line) 210. Outside of the cryostat, the low pressure line 210 preferably has an internal diameter of around 4.6 mm, the high pressure line 200 preferably has an internal diameter of around 1.4 mm and the chosen material is 316 stainless steel, but other materials can also be chosen. The wider diameter line 210 is provided to minimise flow impedance of the fluid when returning to storage 220 (either via a cold trap 230 or via relief valves), whereas the narrower diameter line 200 is provided to minimise dead volume of gas in the gas handling system, while opposing a reasonably low impedance to fluid flow.

Inside the cryostat 240, the line 212 preferably has an inner diameter of around 0.14 mm and is made of a cupronickel capillary, with wall thickness preferably not less than around 0.18 mm to withhold pressure. This is to minimise both dead volume of ³He and heat flow between cryostat plates.

As will be apparent from FIG. 4, the gas handling system comprises a room temperature section 224 and the section inside the cryostat 240, indicated by the dashed line. Elements 50K, 4K, CP, MXC and NS in FIG. 4 represent the different temperature stages within the cryostat 240; where elements CP, MXC and NS represent the cold plate (CP), the mixing chamber plate (MXC) and the nuclear stage plate (NS). The digital pressure gauge is used for accurate pressure measurement at a 1 mbar resolution used to control precisely the amount of gas transferred.

Thermalisation at each plate inside the cryostat is achieved by silver brazing a spiral of around 10 turns of the CuNi capillary around a copper bobbin having an outer diameter of around 6.5 mm (¼″), and clamping the bobbin to the plate with, preferably, a brass screw. Brass contracts more than copper on cooling and therefore improves the thermal contact between the bobbins and the plates.

The capillary 214 connecting the cell 250 to the filter 260 is preferably dimensioned to keep heat flow to the nuclear stage below 1 nW in the following operating conditions:
mixing chamber temperature: T_{MC}=30 mK
nuclear stage temperature: T_{NS}=1 mK
capillary material: CuNi
capillary inner diameter: ID=0.14 mm
capillary outer diameter: OD=0.50 mm.

Within these conditions, the capillary length Lc is greater than or equal to 2.5 cm. In the preferred design, the capillary is 50 cm long. When filled with ³He at 0 bar, this adds power P of around 50 pW to the nuclear stage (P_{capillary}=10 pW and P_{3He}=40 pW). In this way, using a thin capillary of the described properties, or similar, the disclosed cooling system can operate with liquid cooling medium in the cell and in the capillary, without the need to evacuate the capillary to reduce the heat load on the refrigerator system used. The gas handling system is designed to operate safely at working pressures ranging from 0 bar to 60 bar, or more.

The apparatus is preferably configured, as disclosed above, in order to ensure that the capillary, going from room temperature down to the lowest temperature stage of the refrigerator when filled with thermalising material, does not introduce a thermal short between the different temperature stages of the refrigerator, which could spoil its performance. For this purpose, the heat leak between consecutive hotter and colder temperature stages in the refrigerator, introduced by the capillary and the thermalising medium inside, is made smaller than the cooling power of the respective temperature stage. This condition allows the operation of the quantum circuit inside the cell when both the cell and the capillary are filled with thermalising liquid, with no requirement to seal of the cell once filled and remove the thermalising agent from inside the capillary. This is achieved by using a capillary with a small cross-and section of a material that is a poor thermal conductor (in the preferred implementation CuNi is used) and with a small inner diameter to keep the cross-section of thermalising media inside the capillary sufficiently small.

As described above, thermalisation at each plate inside the cryostat is preferably achieved by silver brazing a spiral of around 10 turns of the CuNi capillary around a copper bobbin having an outer diameter of around 6.5 mm (¼″), and clamping the bobbin to the plate with, preferably, a brass screw.

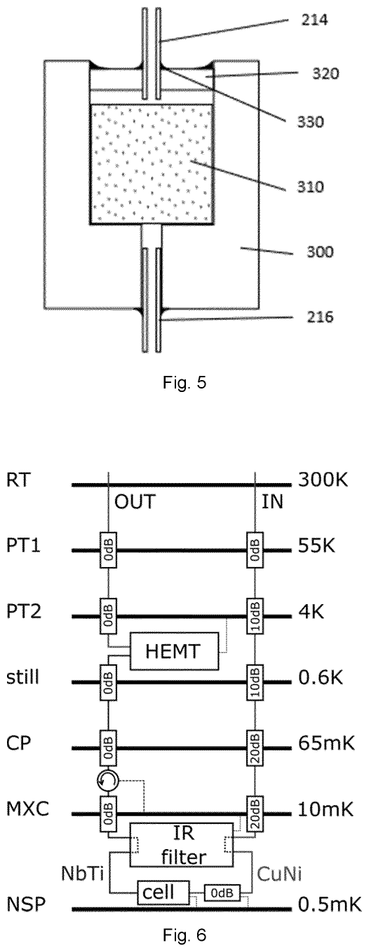

The design of the filter 260 on the mixing chamber plate, the purpose of which is to prevent high frequency noise from entering the cell 250 through the filling capillary, and improve thermalisation of the cooling liquid entering the cell through the large surface area provided by the sinter to the refrigerator cold plate, is represented in FIG. 5. Without the filter thermal radiation can freely propagate from one end (room temperature) to the other (inside the cell), thereby spoiling operation of the quantum circuit. The filter 260 comprises a body or housing 300 preferably made of copper, having one end through which the capillary 216 to the CP plate passes, and the opposite end closed by a copper lid 320, the lid 320 having an aperture for the passage of the capillary 214 to the cell. The lid 320 is sealingly fixed to the housing 300, for example by solder joints 330. The housing 300 provides a chamber filled with, preferably, silver (Ag) sinter 310, which forms the filtering element. The sintered silver powder 310 preferably grain size of 1 micrometre or less, pressed inside the housing 300, which preferably has a length of around 0.5 cm in this embodiment.

The filter 260 at the MXC temperature stage is used for thermalisation of the cooling liquid to the MXC temperature.

The microwave filter disclosed herein, as well as being useful for the input line for the cooling fluid to the cell, could be used to separate cells as well, sharing the same ³He bath, thereby providing high frequency shielding between the cells.

With reference again to FIG. 4, the adsorption pump 271 is a sealed volume connected through a line 200 to the rest of the gas handling system and preferably contains m_{charcoal}=25 g of activated charcoal as the adsorbent material. The adsorption pump is inserted into a low temperature environment 270 and cooled to a temperature of around 4K, preferably by insertion into liquid ⁴He, in order to adsorb an amount of cooling medium (preferably ³He) from the gas handling system. The adsorbed cooling medium can then be released from the adsorption pump and directed to other parts of the gas handling system by raising the temperature of the adsorption pump 271, preferably by removing it from the low temperature environment 270. The body of the adsorption pump 271 is preferably made of austenite stainless steel (316L), which preserves its mechanical properties in liquid helium.

To prevent pressure oscillations due to temperature fluctuations of the different temperature stages inside the refrigerator, when operating the ³He in the cell at elevated pressures, a ballast volume 280 is preferably connected to the fill line at room temperature. The ballast volume 280 has preferably a volume which is 10,000 times larger, or more, than the internal volume of the cell and fill line. In a preferred implementation the ballast volume is 60,000 times larger than the internal volume of the cell and fill line, and the temperature of the gas that it contains is regulated.

In some embodiments, multiple gas handling systems connected to the same cell may be used for templating of separate layers of solid ³He or ⁴He at the surface of the quantum circuit. This may be the preferred solution if it is desired to maintain the purity of ³He. In another preferred implementation, a single gas handling system using two storage volumes 220, one with ³He and one with ⁴He can be used. In another implementation a single gas handling system with a single storage volume 220 filled with a mixture of ³He and ⁴He, and only a very small amount of ⁴He, can be used to pre-plate the quantum circuit with ⁴He as a result of the greater absorption efficiency of ⁴He over ³He.

### the Control Signal System

Referring now to FIG. 6, the quantum circuit control signal system down to the mixing chamber can be of a form that is known for dilution refrigerator systems. Coaxial cables are used to bring microwave signals to and from the quantum circuit. Preferably, the coaxial cables are 0.86 mm CuNi—CuNi for the input line(s), 0.86 mm NbTi—NbTi for the output line(s) up to the HEMT amplifier(s) and 0.86 mm CuNi—CuNi for the output line(s) between the HEMT amplifiers(s) and the room temperature plate.

The quantum circuit control signal system may consist of any number of input and output signal lines, and they may be configured differently depending on their use. A signal line can, as in the implementation show in FIG. 6, be a microwave line supporting signals at GHz frequencies (1-10 GHz typically), or it could be a low frequency line supporting signals with frequencies from 0 Hz up to 1 GHz.

The input line between the IR-filter (thermalised to mixing chamber plate) and the cell is preferably interrupted with an additional 0 dB attenuator, which is thermalised to the nuclear stage plate. This enables thermalisation of the central core of the coaxial cables before connecting to the cell, while minimising microwave dissipation at the nuclear stage. The coaxial cables connecting the IR-filter to the nuclear stage plate (either via the cell or the attenuator on the plate) are advantageously dimensioned to keep both passive and active loads to the nuclear stage below 100 pW per line in the following operating conditions:
mixing chamber temperature: T_{MC}=30 mK
nuclear stage temperature: T_{NS}=1 mK
materials for drive line: CuNi-PTFE-CuNi
materials for output line: NbTi-PTFE-NbTi
coax dimensions (OD-PTFE OD-core OD): 0.86 mm-0.66 mm-0.20 mm
max input power at the cell: −82.4 dBm

Within these conditions, the coaxial cable lengths preferably are L_{CuNi}≥8 cm for the CuNi drive line and L_{NbTi}≥0.7 mm for the NbTi output line. To satisfy the active load condition P_{active}≤100 pW when Pcell=−82.4 dBm (assuming that the dissipated power in the coax equally distributed between nuclear stage plate and mixing chamber), the CuNi coax length L_{CuNi}≤115 cm (this also includes the CuNi coaxial cable between the 0 dB attenuator and the cell). The dissipation in the NbTi coaxial cable is negligible compared to CuNi, hence there are no practical limitations on the maximum length of the NbTi output lines.

### The Cell

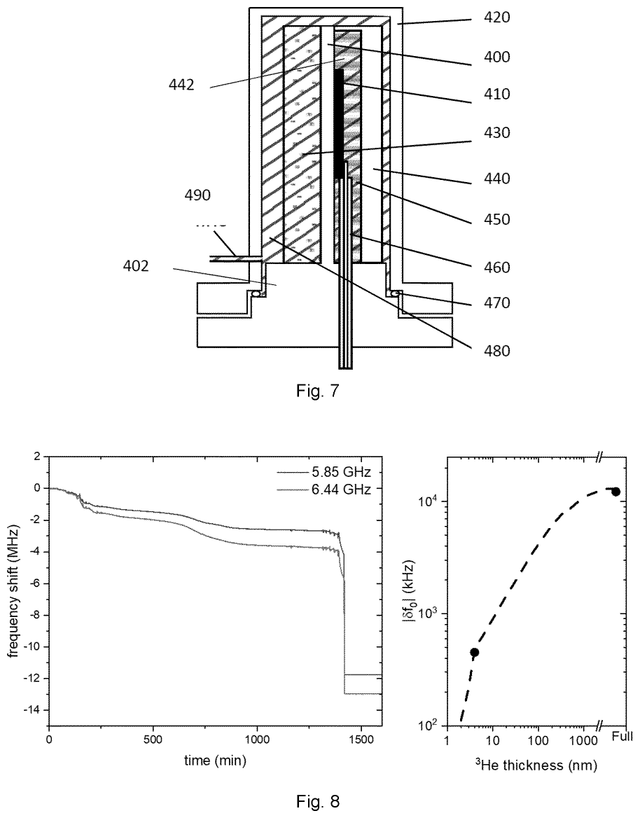

The cell, or enclosure, can be considered to comprise three main elements: the quantum circuit (sample) holder, an optional sample cover and the lid. Each of these elements is formed of different parts that have specific functions. The whole cell, specifically the three elements and their constituent parts is represented in FIG. 7. The following describes each of the elements, their parts and their functions.

In FIG. 7, the oblique stripes represent the volumes filled with liquid ³He (in this embodiment), the dotted area represents the sinter and the wavy area represents the microwave cavity, which is also filled with liquid ³He.

The sample holder, for holding the quantum circuit 410, comprises a sample holder body 400, silver sinter 430 and hermetic microwave feedthroughs 460. Its functions are:
cooling the helium liquid
supporting and securing the quantum circuit (sample)
forming one side of the microwave cavity (where the quantum circuit is located)
connecting the quantum circuit to the signal control system
completing part of the leak-tight vessel for the liquid helium (in the normal or superfluid state)
providing high frequency shielding to the inner volume of the cell.

The body of the sample holder 400 is preferably made of oxygen-free high conductivity (OFHC) copper, with residual resistivity ratio (RRR) exceeding 100. The body 400 preferably has a step-shaped profile at its base 402 for accommodating an indium seal 470 preferably capable of holding 50 bar at least. The cell body 400 is directly thermalised to the cryostat coldest temperature stage and provides cooling to all the other components of the cell.

The body 400 is drilled through to receive microwave feedthrough connectors 460 as illustrated in FIG. 7. These connectors 460 are hermetic in order to prevent liquid ³He or ⁴He 480 in the normal (non-superfluid) or superfluid state from leaking out of the cell. In a preferred implementation the connectors are made from glass dielectric and metal body.

The silver sintered heat exchanger 442 is pressed directly onto the sample holder body 400 to maximise thermal conductance of the cooling liquid to the body 400, which in turn is well thermalised to the cryostat base plate. The sinter 430 is made with silver powder of typical grain size d_{grain}≤1 micrometres with a packing fraction p≤50% (density≤5 g per cm³). In a preferred implementation the sinter has a grain size in the region of 70 nm, and is silver sinter. The heat exchanger is dimensioned to maintain deltaT=T_{3He}−Tₛᵢₙₜₑᵣ≤10 microK in the following operating conditions:
nuclear stage temperature: T_{NS}=400 microK
heat load dissipated in the liquid ³He bath from the quantum circuit: Pdissipated=2 pW.

Within these conditions, the required surface area of the sinter is Aₛᵢₙₜₑᵣ≥0.5 m², which corresponds to mₛᵢₙₜₑᵣ>0.25 g of sinter. In the present implementation we estimate a total siter area Aₛᵢₙₜₑᵣ>10 m².

The functions of the sample cover 440 are:
forming the other side of the microwave cavity
reducing the needed volume of liquid inside the cell.

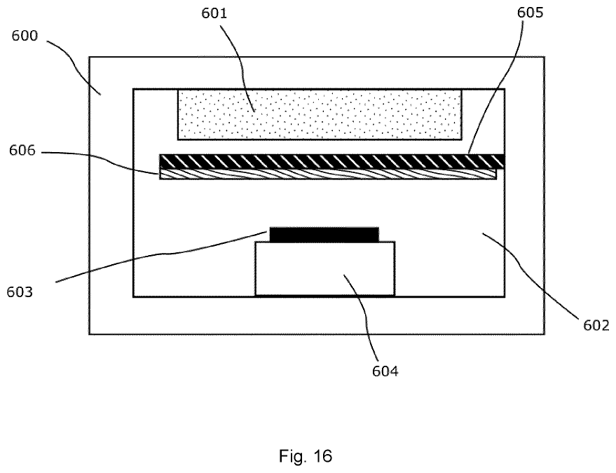

In an example implementation, the total sinter area was 24.1 m². In a preferred implementation the sinter material is placed within the sample enclosure sufficiently far away from the quantum circuit chip as not to introduce additional losses or decoherence. For example on the opposite side of a copper plate which holds the sample, such as to make the sinter face away from the sample and cover a volume below the sample where no electrical signals propagate from the sample. Further details of this characteristic of the preferred implementations, applicable to all the embodiments disclosed herein and contemplated thereby, is provided below in connection with FIG. 16.

The body of the sample cover 440 is preferably made of OFHC copper and is screwed onto the sample holder body 400. The microwave cavity 450 is formed by the bodies of the sample holder 400 and the sample cover 440. This volume is also filled with bulk liquid helium 480. The cavity side of the sample cover is profiled to maximise the compatibility between the measured quantum circuit (sample) and the cavity.

The lid is composed of the lid body 420 and the fill line 490. Its functions are:
completing part of the leak-tight vessel for the liquid helium (in the normal or superfluid state)
connecting directly to the fill line for liquid helium
providing high frequency shielding to the inner volume of the cell.

The body 420 of the lid is preferably made of OFHC copper. The fill line 490 is preferably attached to the lid 490 as this allows the quantum circuit to be prepared and mounted to the sample holder body separately, for example on a bench, without having to disconnect the fill line 490 from the cell. The hermetic seal 470 to confine the liquid helium is provided by the stepped indium seal. In some implementations the fill line can also be attached to the sample holder body 400.

In the preferred embodiments, the cell is desirably designed to withstand high pressures of the liquid coolant inside, preferably up to 60 bar or more.

### Method of Introducing Liquid Cooling Medium

At T=10 mK the viscosity of liquid ³He is very high and it takes a considerable amount of time to fill the cell through a small capillary. To fill the cell, the base temperature is preferably raised to about 200 mK (or more) and then small ‘shots’ of gas (that are condensed into fluid by the cold stages in the cryostat) are let in one at a time from the gas handling system. A single ‘shot’ is let in by opening/closing relevant valves on the gas handling system at which point the pressure on the gauge connected to the capillary volume is used to monitor the condensation of ³He. A pressure of 0.1-3 bar is applied and then the gas handling system sealed off until the pressure in the capillary drops as a result of ³He condensation. When the pressure is sufficiently low another ‘shot’ is let in until a specific amount of ³He has been injected into the cell such that it is at the desired level. A quantum circuit can be used as a ‘level meter’ indicating when the liquid level is above the quantum circuit (see FIG. 8). Another implementation envisages having a second quantum circuit (for instance a superconducting resonator) placed above the actual quantum circuit and acting as a level meter. In another embodiment, multiple quantum circuits can be geometrically positioned at different heights and acting as level indicators. This procedure can either be conducted by manual operation of the gas handling system, or by implementing a computer software-controlled system performing the same functions.

### Results

### Evidence of Presence of ³He Liquid

FIG. 8 shows the time evolution of the resonance frequency (measured using a vector network analyser, VNA) of two superconducting resonators as ³He is introduced into the cell. Specifically, FIG. 8 (left) shows the superconducting resonator frequency shift as ³He is introduced into the cell. The two traces show two resonators with resonance frequencies of 5.85 GHz and 6.44 GHz respectively.

Small shifts in frequency are seen as liquid accumulates at the bottom of the cell and coats all surfaces in a thin film layer. At t=1400 min a sharp jump in frequency is seen, corresponding to the liquid level going above and covering the whole resonators. The relative total frequency shift from t=0 to t=1600 (that is, empty cell and full cell) corresponds to the expected change in frequency due to the ³He relative dielectric constant of 1.0426. The measurements agree within 2%. This is shown in the right panel of FIG. 8, where for the 5.85 GHz resonator the measured frequency shift for two cases (round markers corresponding to full cell, and 10 monolayers ˜4 nm thick film) are compared to expected shift based on electrostatic simulations, showing that the resonators can be used as level meters.

### Evidence of Cooling Surface Spins

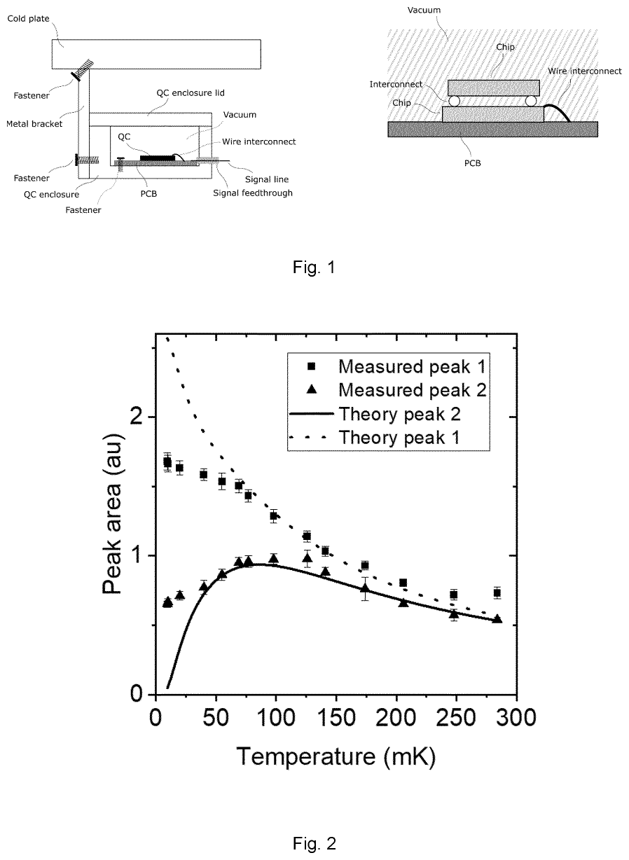

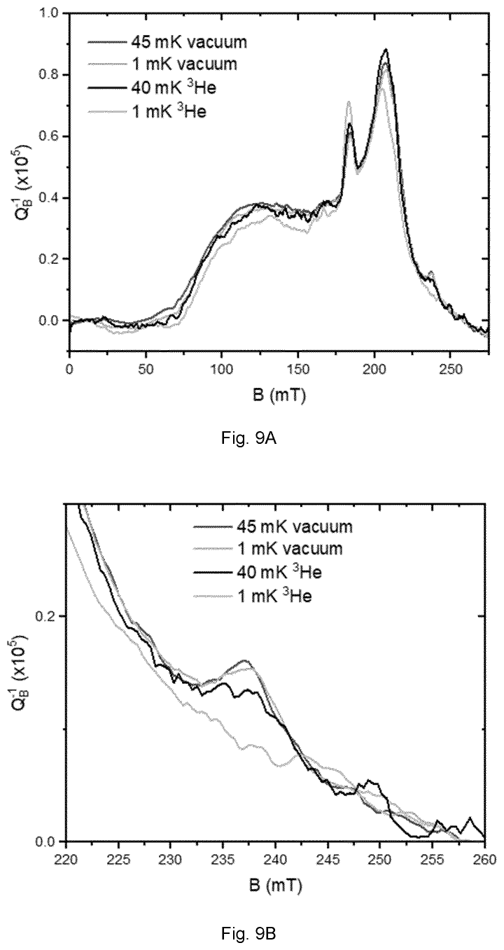

The effect of ³He can be seen on the surface spins present in the device and coupling magnetically (note TLS causing resonator frequency noise and loss couple electrically) to the resonator. FIGS. 9A and 9B show the electron spin resonance (ESR) spectrum obtained in situ in the resonator. The y-axis shows the additional loss as a magnetic field is applied, with zero field loss subtracted. The spectrum has several features and herein focus is given in particular to the rightmost peak arising from atomic hydrogen in the quantum circuit. It is connected to the leftmost of the three peaks present, hyperfine split by h*1.4 GHz in energy, where h is the Planck constant. The relative intensity of these peaks thus acts as a thermometer, the intensity given by the Boltzmann distribution between the two. The peak is present when quantum circuit is in vacuum both at T=50 mK and T=1 mK of the cryostat base plate, and of similar intensity. This means the surface spins are not cooled beyond 50 mK, as previously seen also in the art. When ³He is present in the cell but the cold plate is maintained at 40 mK, no qualitative difference is observed in the data compared to the 50 mK empty cell data (see FIG. 2). However, when the cold plate is cooled to 1 mK, the third peak completely disappears, meaning these hydrogen surface spins are cooled to lower temperatures. Hence ³He cools surface spins very efficiently.

### Evidence of Cooling TLS

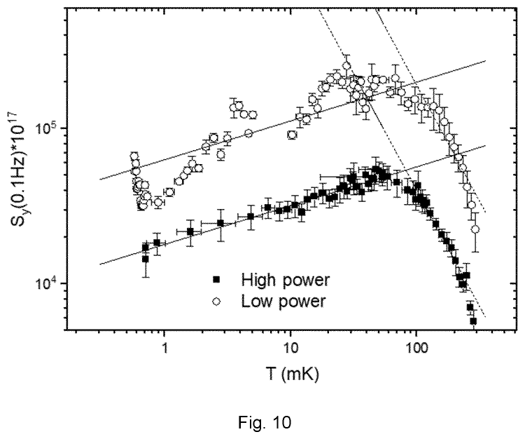

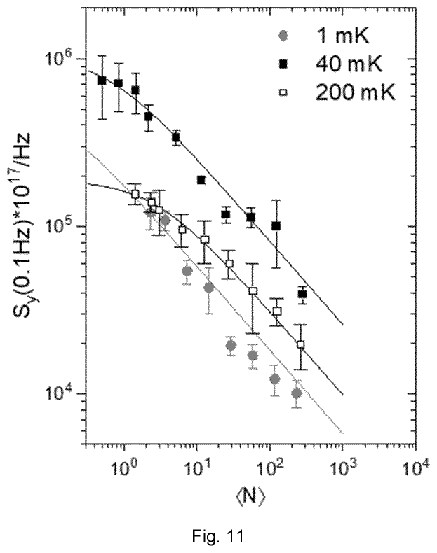

FIG. 10 shows the magnitude of the frequency noise measured in a superconducting resonator versus the cryostat (NS stage) temperature.

Specifically, FIG. 10 shows superconducting resonator frequency spectral noise density normalised to the resonance frequency (6.44 GHZ) at 0.1 Hz versus the temperature of the cold plate of the nuclear demagnetisation stage (NS) used to achieve temperatures well below 1 mK. The NS is mounted at the dilution refrigerator base plate and provides one additional cooling step. What can be seen is the well-known dependence of the noise at high temperatures: noise increases as the temperature decreases with a scaling of the noise as T^{-1.5}. There is then saturation and below a threshold of 30-40 mK noise appears to decrease instead. However, the inventors have discovered that this is not the noise itself decreasing, instead the system crosses over to a regime of TLS saturation. The red data taken at low powers has certain features causing the noise magnitude to vary by a factor about 3 over time. These are temporal fluctuations due to TLS material defects. At high microwave powers (number of photons in the resonator N˜400) these TLS are saturated. The timescale is about 6 days to go from 1 mK to 300 mK.

The data shown (Sy) is the extracted magnitude of the power spectral density at 0.1 Hz, a region of the frequency noise spectra that is dominated by 1/f-type TLS noise. The y-axis is scaled with the resonator frequency (convention). In this Figure two datasets are shown taken at different power levels in the resonator (photon number N). At higher power more TLS are saturated. The noise follows the expected trend of increasing noise with decreasing temperature down to around 50 mK. Then, the noise dependence reverts and the noise again appears to decrease below around 30-40 mK. This cross-over relates to saturation of TLS. At high temperatures the system is in a moderately weak electric field regime (N˜N_{c}) where we expect the noise to scale as T^{-1-2μ}, where μ is a positive number smaller than 1. This is indicated by the dashed lines in FIG. 10 using μ=0.25. Below a crossover temperature of ˜80 mK the noise then starts to decrease upon cooling. This regime is discussed in further detail below.

The ‘low power’ dataset shown (number of photons in resonator N˜40) is less smooth than the ‘high power’ dataset. This is because of temporal fluctuations of TLS: during the course of the measurement (around 6 days) strongly coupled individual TLS drift in and out of resonance with the resonator causing a temporal increase in noise. Hence the fluctuations in the ‘low power’ data shall be regarded as additional on top of the generic trend which is due to a large ensemble of weakly coupled TLS. At high power the strongly coupled TLS are easily saturated and the remaining trend is the ensemble trend. It is expected to look the same as the ‘high power’ data, shifted towards higher noise level and with a cross-over temperature weakly shifted towards lower temperature.

This can be verified by measuring instead the power dependence of the noise at a fixed temperature (FIG. 11), where it can be observed that noise that decreases with increasing power (photon number N) according to S_{y}=A₀/\sqrt{1+N/N_{c}} where A₀ is the magnitude of the noise at zero photons and N_{c} is a critical photon number for saturation, determined by the properties of the TLS, their coupling and the resonator geometry. This measurement is done at a given temperature on much shorter timescales (10 hours) and is thus less susceptible to temporal fluctuations. The same trend is present both at the maximum of the noise (T=40 mK) and at T=1 mK. This means it is possible to rely on the high power data in FIG. 10 for determining the general trend of the noise, avoiding the issues with TLS long-term temporal fluctuations.

FIG. 11 shows the power dependence of the noise at three temperatures, showing that the scaling with power (photon number n) follows the expected dependence due to TLS both above, near, and well below the threshold temperature, showing that we are near the weak fields regime of saturation. Quantum circuits are typically operated in the limit N˜1.

It is noted that the fact that the noise follows a clear trend of reduced noise with the same power law scaling down about 1 mK means that cooling is efficient also for the TLS subsystem. Hence immersion in ³He:
Cools down surface spins (that contribute to flux noise)
Cools down TLS
The fact that the ‘high power’ noise follows the expected power law (linear in log-log scale) all the way down to around 1 mK means that we can use the noise to validate thermalisation of the TLS-bath down to around 1 mK.
Takes away excess heat from the quantum circuit caused by dissipated control signals
Cools down control lines themselves, and any resistive interfaces for signal propagation introduced thereof, inside the cell, sufficiently not to overheat the TLS and spin bath.
Operation with ³He at zero (almost zero) saturated vapour pressure leads to a stable ³He liquid and pressure fluctuations does not cause an issue (³He has a dielectric constant that depends on pressure) with increased noise
³He dielectric loss tangent is very low and does not introduce significant additional loss in the quantum circuit as to impact its performance, with an upper bound of tan δ˜1e-5, limited by device sensitivity, likely much lower than that.
Allows us to choose the desired or optimal operating temperature of the quantum circuit by adjusting the cold plate temperature using a heater to the desired temperature.

The leak-tight enclosure with no dielectric seals (apart from signal line ports) or gaps efficiently protects the quantum circuit from stray thermal photons (from other temperature stages in the cryostat). The observed reduction in TLS noise also confirms that there are no other sources of heating that limit the temperature. That is, all other major sources of heat are also effectively taken care of. It is expected that the ³He also improves thermalisation of input lines and (and amplifier stray thermal radiation) as well as provides damping of the phonon environment of the quantum circuit.

It is also expected that ³He immersion may:
Reduce qubit residual thermal photon population further
Lead to a lower quasiparticle density
More efficiently mitigate the effect of high energy particle impact events
Protect the quantum circuit from phonons that cause decoherence and excite quasiparticles
³He can form a shield that absorbs cosmic particles before it reaches the quantum circuit
³He also has another significant effect on the TLS bath, as is described below.

### Full Immersion in ³He is Highly Advantageous

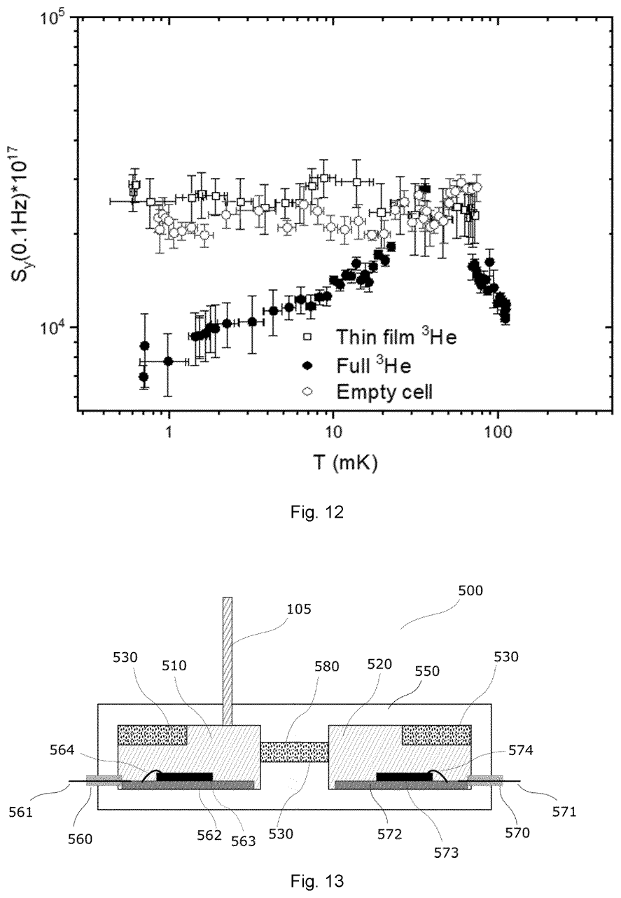

FIG. 12 shows what happens to noise when the cell is full with ³He, and the case when there is only a little ³He in the cell. Note that the data presented in FIG. 12 is for a different resonator (with a different frequency) than the data presented in FIG. 10. In small amounts, the ³He will initially coat surfaces in the whole cell in a thin layer (few nanometres) and then accumulate at the bottom of the cell as more ³He is added. For the data shown in FIG. 12 it is estimated that 4 nm of ³He is covering the device surface, deduced from the observed frequency shift. The thin film of ³He is expected to have much worse cooling effect on the quantum circuit as compared to the filled cell. This is also seen in FIG. 12, where the noise is constant below 100 mK. The situation is very similar when the cell is in vacuum (empty cell), as also shown in FIG. 12. FIG. 12 also shows the saturation occurring at about 100 mK in the empty (no ³He) case, followed by a decrease in the noise with a predicted temperature scaling of μ=0.5, showing that in the empty and thin film cases the TLS are not cooling below about 100 mK.

### Increasing the Energy Relaxation Rate of the TLS Bath

The TLS can be characterised by two rates, the energy relaxation rate Γ₁, and the dephasing rate Γ₂. The noise in a quantum circuit is, in the weak fields regime, governed by Γ₂, whereas the loss is determined by Γ₁. In a strong fields regime saturation takes place and the noise and the loss will depend on both quantities. This is true for each individual TLS and one can also consider an average relaxation and dephasing rate of the TLS bath. In what follows Γ₁ and Γ₂ are referred to as these average quantities. In the usual dielectrics where TLS resides one typically finds Γ₁˜10²-10³ Hz. This is to be compared to the dephasing rate Γ₂ that governs the noise. Usually, one finds Γ₂˜10⁷ Hz at ˜100 mK, and hence Γ₂»Γ₁. Γ₂ scales with temperature as Γ₂˜T^{1+μ}. In vacuum it is thus required to cool to ˜10 microKelvin to reach the crossover Γ₂=Γ₁. This is not experimentally accessible.

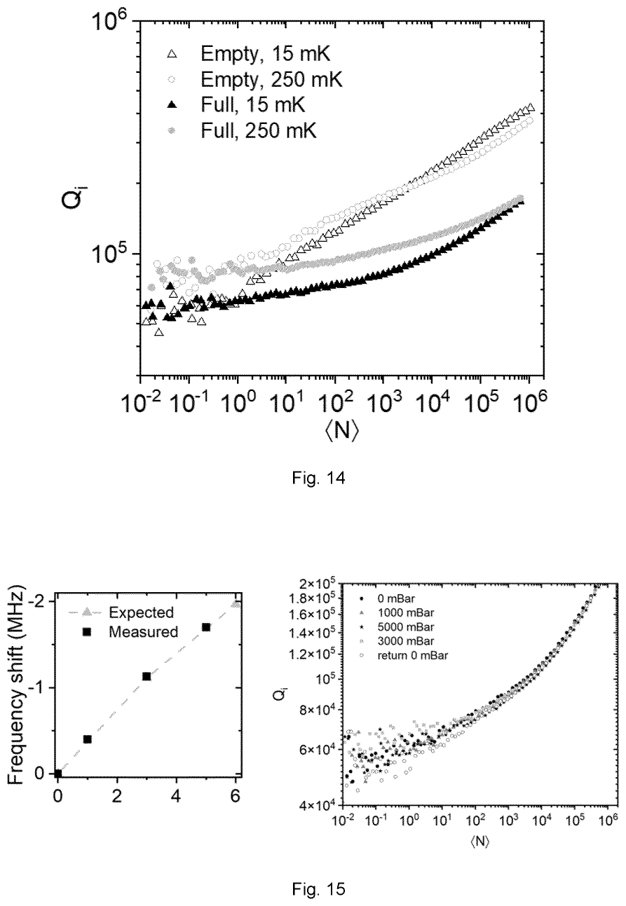

The data in FIG. 14 shows another role of ³He: ³He increases Γ₁ by a factor ˜1000. FIG. 14 shows that the saturation power, i.e. the number of photons required to saturate a given number of TLS, up to a given Quality factor of the resonator, increases about 1000 times when ³He is added to the cell. The saturation power is proportional to the product Γ₁Γ₂. The noise (FIG. 10) shows that Γ₂ is unaffected by the introduction of ³He because noise at high temperature is same with and without ³He. ³He can therefore be used to lift the crossover temperature at which Γ₂=Γ₁ to a much higher temperature 10-100 mK, that is accessible in experiments, potentially permitting to operate quantum circuits in a regime where the TLS bath is relaxation limited. The observed regime where the noise decreases upon cooling is desirable because it has the effect of reducing the noise caused by the TLS bath on the quantum circuit. This is seen at temperatures below 50 mK in FIG. 10.

This results in the realisation that it also becomes desirable from a TLS and noise perspective to reduce the temperature of the quantum circuit further.

FIG. 14 shows the change in quality factor versus average photon number in the resonator with and without ³He in the cell. As can be seen, with ³He present one must increase the photon number by a factor ˜1000 to reach the same Q as in the case without ³He.

### The Role of the Dielectric-³He Interface

The relaxation rate Γ₁ of the TLS bath to phonons is known to be given by

$${Γ}_{1} = \frac{{γ}^{2} {Δ}_{0}^{2} E}{2 {πρυ}^{5}} coth \frac{E}{2 {k}_{B} T}$$

where ∪ is the speed of sound, ρ is the density, γ˜1 eV is a coupling strength, E the TLS energy level splitting and Δ₀ the TLS tunnelling matrix element.

Comparing this expression for typical dielectrics used in quantum circuits for which it is found that Γ₁˜10²-10³ Hz; hypothetically replacing all the material parameters with those of ³He instead yields Γ₁˜10⁶-10⁷ Hz or even higher. An exact estimate is not possible without measurement of γ, which is not known in the art. Yet the estimate is more than 10 times higher than what is observed in FIG. 14. The reason for this, the inventors have discovered, is that the coupling between TLS (residing in dielectrics, near the surface) is not perfect to ³He.

Changing pressure in the chamber will modify the properties of ³He, changing its density and speed of sound. A pressure increase from 0 to 5 bar changes these quantities by ˜30%. Putting this into the equation for Γ₁ above, where speed of sound enters in fifth power, one could expect a large change if bulk ³He is the main limiting factor for this additional TLS relaxation.

Referring now to FIG. 15 it is evident that for large N all Qi(N) measurements for different pressures almost collapse onto the same curve, meaning that the bulk properties of ³He (density, speed of sound) that are expected to influence phonon propagation have no significant influence. There is a very small effect (saturation power increases <20% by increasing pressure to 5 bar, the opposite direction to expectation). This implies that the limiting mechanism for energy relaxation lies in the interface between ³He and the TLS medium (dielectric), and it can be expected that this coupling can be increased by several orders of magnitude by engineering the interface. It is desirable to increase the coupling between TLS and ³He because it improves thermalisation of the TLS bath, meaning that it is less prone to leak energy into the quantum circuit under operation and thus spoiling its quantum state. As shown in FIG. 10, the noise due to the TLS bath also reduces meaning that dephasing due to frequency fluctuations in superconducting quantum circuits can be suppressed by going to lower temperatures and/or achieving stronger coupling between the TLS bath and ³He.

In connection with FIG. 15 showing the effect of applying pressure to the ³He, the left hand graph verifies that pressure is applied. The measured frequency shift of the resonator originates from a change in the dielectric constant of ³He with pressure, which is calculated from the Clausius-Mosorotti relation. Measured frequency shift is in very good agreement with the theoretical expectation. The righthand graph shows the (lack of) effect on the saturation power.

With the goal of increasing the coupling between ³He and TLS bath several approaches may be pursued individually or in combination:
1. Apply pressure, up to 60 Bar or more, depending on GHS components used and immersion cell design with the aim of achieving more densely packed atoms near the surface/interface. This will increase the number of solid layers until the whole ³He bulk volume becomes a solid. Where this transition happens and the number of layers formed depends on temperature, and adaptive cooling may also be pursued to control the amount of solid layers based on the measurement of some quantity, such as but not limited to loss in the strong fields regime.
2. Surface templating: pre-coat the surface with thin layers (from less than one atomic layer up to a few nanometres) of ⁴He and or ³He in any order before filling the cell completely with ³He. Due to van der Waals interactions, ³He atoms adsorb to surfaces and modify the device/liquid interface. This interaction results in up to a few layers of solid ³He on the surface, the number of layers depending on temperature and pressure. To realise such templating, two gas handling systems (of the type described herein) may be connected to the same immersion cell, one supplying ³He and the other supplying ⁴He. In another embodiment, a single gas handling system with multiple gas storage volumes can be used. A small amount of either gas is then let in to the cell at a time, in the desired order, and it is allowed to condense in the cell until the next layer is introduced.
3. To introduce a layer or sub-monolayer of electronic spins on the surface that mediates dipole-dipole electron-nuclear coupling to the nuclear spin of ³He.
4. To process or coat the quantum circuit surface with a thin layer of dielectric material with the purpose of modifying the interface.
5. To increase the effective surface area of the quantum circuit containing the TLS by making it more rough or perforated.

### Choice of Cooling Liquid

At mK temperatures there are only two known liquids that are suitable: ³He and ⁴He or a mixture of the two.

⁴He has a superfluid transition of 2.17 K at saturated vapour pressure whereas ³He has a superfluid transition about 0.9 mK at saturated vapour pressure. The thermal conductivity of superfluid ⁴He at low temperatures is poor; the density of phonon excitations is vanishingly small and conduction due to thermal counterflow of the normal and superfluid components, which dominates near the superfluid transition, is also negligible. On the other hand, the thermal conductivity of liquid ³He in the normal state (and dilute solutions of ³He in ⁴He) increases in proportion to inverse temperature. Limited results, and theory, show that the thermal conductivity in the superfluid state is not strongly impaired. Thus ³He (or dilute solutions of ³He in ⁴He) are expected to be effective cooling fluids compared to ⁴He at mK temperatures. However, this is not certain as cooling is not only based on the thermal conductivity of the liquid. It also is strongly dependent on the thermal conductivity through the boundary (Kapitza resistance) of the liquid and the material it is cooling down. Not much is known about such interfaces and the thermal coupling of helium liquids to the constituents of quantum circuits. In the case of quantum circuits it cannot be said to be known what the Kapitza resistance between the circuit, its environment and ³He or ⁴He would be. Not only has it not been studied in detail, but it is not even known with certainty what constitutes the surface of quantum circuits: these have complex surface chemistry which are exposed to ambient conditions meaning they are covered in layers of water and hydrocarbons resulting in a complex chemistry and unknown mixture of surface species. This is the challenge in the art for quantum circuits. The art does not understand what the material nature of TLS is and how the surfaces and interfaces behave microscopically on the relevant energy scales (<10 mK). So it is not possible to predict how ³He or ⁴He will (or will not) cool a quantum circuit and the physical subsystems coupled to it that give rise to decoherence and noise.

The system and method disclosed herein provide for the effective cooling of quantum circuits and processor units and their environment to significantly lower temperatures than have been achieved in the past. Specifically, as described above, while prior art systems had sought to cool circuits below 50 mK, the systems did not in practice achieve this as they relied on cooling of the substrate on which the quantum circuit was disposed. As a consequence of inefficient cooling and the generation of heat during operation of the quantum circuit, the actual operating temperature was in the region of 50 mK or higher. Given the lack of a solution that demonstrably achieves further cooling of the quantum circuit and its environment, and certain processes are understood to result in degraded performance at lower temperatures, achieving a temperature around 50 mK was not considered disadvantageous, but rather the best compromise that can be easily achieved.

The known systems are not suitable for cooling quantum circuits below this level as they are not able to mitigate the heat generated during operation or cool down various components of the environment sufficiently.

The method and system taught herein are able to cool quantum circuits and their environment to temperatures significantly below what was previously achieved and specifically well below 50 mK, in practice to 10 mK and lower, in dependence on the refrigerator used. In practice, this is achieved by creating an environment within which the quantum circuit is held, of very low-loss and low temperature fluid, ³He being preferred. While it is possible with the disclosed system and method to cool significantly below 10 mK, the inventors believe for the reasons set out above in detail that this will not necessarily achieve optimum functioning of the quantum circuit. However, the optimum temperature is in many cases likely to be below the readily achievable ˜50 mK the art has settled on, depending on the application and purpose of the quantum circuit.

The cooling characteristics of the environment are obtained by means of an enclosure made of a highly conductive metal, copper being preferred, which can be cooled to very low temperatures (10 mK or less). The enclosure is preferably constructed so as to present a large surface area of cooling metal to the fluid (³He) so as to impart maximum cooling to the fluid. The large surface area can be achieved by the addition of an internal surface or coating to the enclosure which could be described a textured or porous. In an embodiment, this is by a layer or block of sintered metal powder, such as silver, although other materials could be used including copper, gold and so on. In other embodiments, the chamber of the enclosure, within which the quantum circuit is held, may be filled with sintered powder (again of silver, copper or gold, for example).

The advantage of such a structure is that the enclosure can be kept small, which optimises the performance of the system and also reduces the amount of material required, particularly ³He which is expensive.

The system and methods are also configured to control cooling of the quantum circuit in the enclosure by a variety of means, including controlling the amount of and/or pressure of fluid coolant in the enclosure. Control can be determined from a number of factors, including measuring actual temperature of the quantum circuit, measuring other parameters which depend on the temperature of the quantum circuit, such as its state of operation and so on. Controlled cooling makes it feasible to provide a system and method that can achieve adaptive cooling of one or more quantum circuits, in order to seek to keep the quantum circuit(s) at their optimum performance. This can be achieved by measuring one or more parameters, as disclosed herein, and also by measuring changes in performance of the quantum circuit and changing the setpoint temperature to optimise that performance, in particular improved coherence. Adaptive cooling can be applied at the start of an operating state of a quantum circuit or in the course of its operation.

In particular, the described method and system of adaptive cooling, are able to reach and maintain the optimal temperature of the quantum circuit, whatever the optimal temperature might be. Such adaptive cooling might be either static, or dynamic where a performance metric related to the quantum circuit is optimised against temperature. Different quantum circuits may have different optimal temperatures depending on the specific influence of various physical mechanisms causing degraded performance on the key quantities relevant for operation of the quantum circuit and its specific application. Different quantum circuits that otherwise have the same application or functionality may still have different optimal temperatures depending on the way they have been implemented. Such performance metrics could be properties of directly measured physical systems such as:
Noise from charged material defects or paramagnetic impurities (charge noise or flux noise)
Coherence
Thermal excitation probability of qubit states
Phonons
Quasiparticle density or parity switching events
Losses
Temperature-dependent superconductor properties

Similarly, performance metrics could be inferred from the device operation, such as:
Qubit relaxation or dephasing times
Single- or multi-qubit gate fidelity
Error rate of a logic qubit (constructed from multiple physical qubits)
Fidelity of a particular algorithm, or class of algorithms or sub-algorithms, run on a quantum processing unit
Fidelity of a particular quantum gate operation
As to minimise the need for repeated re-calibration of the quantum processing unit to achieve optimal performance.
The sensitivity, stability, or signal-to-noise ratio of a quantum circuit operated as a quantum sensor (e.g. magnetometer, charge sensor, single photon detector, and so on)

A combination of parameters listed could also be used in the evaluation of the optimal temperature.

In certain circumstances it might also be desirable to vary the temperature of the quantum circuit, or the cooling power provided by the ³He cooling system, during operation. For example, while doing less resource intensive calculations on a quantum processing unit only parts of the circuit may be utilised and thus heat dissipated is low, hence, to sustain the optimal temperature of the circuit a reduced cooling power of the ³He adaptive cooling system may be required. For example when conducting resource intensive calculations utilising the full quantum processing unit more heat may be dissipated and the cooling power of the ³He cooling system may need to be increased to meet the same optimal operation temperature.

To implement such adaptive cooling a feedback loop can be used: a relevant quantity is measured and deviation from optimal temperature is determined using some algorithm. The algorithm determines the new target temperature which is realised by increasing or decreasing the heating of (power supplied to) a resistor mounted on the cryostat cold plate which is thermally linked to the quantum circuit as described.

With reference to FIG. 13, this shows an embodiment of apparatus for a unit comprising a plurality of quantum circuits. In this embodiment, the system 500 comprises a housing having the same characteristics as taught herein and shown, for example in FIG. 7, and using the same cooling fluid, preferably liquid ³He, in a configuration where multiple quantum circuits 563, 573 are integrated within the same housing, specifically in a plurality of sub-enclosures 510, 520. An example of such an arrangement is a quantum processing system comprising separate parametric amplifiers connected in series with the output (readout) microwave lines of the quantum processing unit. This would allow bringing the amplifiers (which should be as close to the quantum processing unit as possible to minimise signal loss between quantum processing unit and amplifier) closer to the quantum processing unit with the quantum processing unit being less affected by the additional heat dissipated by the amplifiers. The microwave filter (described above) can also provide a convenient way to separate two microwave environments 510, 520 sharing the same liquid cooling housing (using a sintered volume in-between), cooling liquid being supplied through a single capillary 105.

Referring now to FIG. 13, the sintered powder is shown schematically as volume of sintered material 530 within the sub-enclosures 510, 520 and in a junction 580 between the two sub-enclosures. The quantum circuits 563, 573 are preferably located on respective cooling substrates, such as the enclosure base 550, or on a printed circuit board (562 and 572) as shown in FIG. 13, as previously described. The apparatus also includes individual signal feedthrough paths 560, 570 with signal propagation lines (561 and 571) connected to printed circuit boards (562 and 572) that in turn are for example wire bonded (564 and 574) to the quantum circuits (563 and 573) for control and readout of the quantum circuit in each sub-enclosure. These paths may also comprise feedback paths for individual sensors used in the adaptive cooling and determination of optimal operation temperature of the quantum circuit.

With reference to FIG. 16, the volume of sintered material is preferably carefully located in the enclosure with respect to the quantum circuit.

In some implementations, the sinter can be disposed at a location within the cell, thermalised to at least one of its enclosure walls or to a lid of the enclosure, at a given minimum distance away from the quantum circuit. In other implementations the sinter can be placed within the volume of the enclosure together with one or more screening materials located between the quantum circuit and the sinter volume (an example being shown in FIG. 16). The or each screen is attached (in a preferred implementation using one or more fasteners) to the internal walls, base or lid of the enclosure, whether directly or indirectly. The purpose of the screen(s) is to protect the quantum circuit from the sinter. When a significant portion of electromagnetic fields form the quantum circuit is allowed to extend into the sinter volume, this will result in losses and decoherence, reducing the performance of the quantum circuit. Placing a screen between sinter and quantum circuit can in certain situations attenuate the losses from or imposed by the sinter, allowing it to be placed closer to the quantum circuit than would otherwise be possible, and as a result reducing the volume of the cell that needs to be filled with thermalising fluid.

The screen can in one example be made of a good electrical conductor with low loss, such as copper. In other examples, the screen can be made of a superconducting material, such as Aluminium, Tin or Niobium, having even smaller electrical resistance. It is envisaged also that multiple screens made from both metallic and superconducting material could be used.

Referring to FIG. 16, an enclosure 600 of a type consistent with the above teachings has an internal chamber or volume 602 which is use is filled with a thermalising fluid, preferably liquid ³He and/or ⁴He. Disposed within the enclosure 600, in a preferred embodiment, there is a screen 605 composed of a solid body made from copper which is coated with a thin layer 606 (for example 1 micrometre to 1 mm) of superconductive material (such as Al, Nb, Sn, In) on the side facing the quantum circuit 603, the latter disposed in region 604 of the enclosure.

In each of these implementations the sinter 601 and optional screening plates 605/606 are advantageously placed in such a manner that they are sufficiently far away from the quantum circuit 603, determined by the extent of the electromagnetic fields emanating from the quantum circuit, which is dependent on the implementation and design of the quantum circuit and which typically varies from circuit to circuit. The sinter 601 and screening plates 605/606 are preferably placed at a distance away from the quantum circuit such that the presence of the sinter 601 and any screens 605/606 does not worsen the measured coherence or performance of the quantum circuit 603 compared to the cell implemented without any sinter and screens. The amount of decoherence can be different from circuit to circuit owing, but not limited, to other decoherence and noise mechanisms of the types described above.

An important preferred characteristics of the screen(s) 605/605 is that it or they are disposed so as not completely to restrict the flow of liquid between sinter 601 and the quantum circuit 603. The liquid is required to be able to flow past, that is across the side of screen 601 facing the quantum circuit 603.

In the various embodiments disclosed herein, the sinter may be provided on one or more of the inner enclosure walls, in a sub-enclosure within the main enclosure, on a separate substrate, such as a screen, and so on. The relevant criterion is that the sinter optimises thermal transfer to the thermalising fluid while not interfering with the electromagnetic fields of the circuit.

It will be appreciated that the cooling fluid may be in liquid form, preferably liquid ³He, ⁴He or a mixture of the two.

1. A system for controlling the temperature of a quantum circuit to an operating temperature below 100 mK, the system including:
an enclosure comprising enclosure walls made of thermally conductive material;
a volume of porous media made of thermally conductive material disposed in the enclosure and thermally coupled to at least a part of the enclosure walls;
a substrate for holding a quantum circuit;
at least one source of cooling fluid;
at least one port in the enclosure directly coupled to the at least one source of cooling fluid;
a control unit coupled to the at least one source of cooling fluid for filling the enclosure with cooling fluid to cool the quantum circuit and/or its environment, wherein the control unit is configured to control the supply of cooling fluid to the chamber so as to control a degree of cooling provided by the thermalising fluid in the enclosure and thereby the amount of cooling provided to the quantum circuit.

2-3. (canceled)

4. A system according to claim 1, wherein the volume of porous media is separated from the quantum circuit so as to provide a volume of thermalising fluid between the quantum circuit and the porous media; and
wherein the volume of porous media is located with respect to the quantum circuit such that it is disposed at a distance at which electromagnetic fields from the quantum circuit entering the volume of porous media are small enough as to not reduce the performance of the quantum circuit.

5. (canceled)

6. A system according to claim 4, comprising a screening element disposed between the volume of porous material and the quantum circuit, the screening element being made of at least one of:
(i) at least one of a conductive metallic and a superconducting material; and.
(ii) a layer of superconducting material disposed over a layer of metallic material.

7-8. (canceled)

9. A system according to claim 1, wherein the porous material comprises one of:
(i) textured or porous internal surfaces of the enclosure walls; and
(ii) heat conductive sintered powder or particles.

10. (canceled)

11. A system according to claim 1, comprising a capillary and a ballast volume;
wherein the capillary is a valveless coupling between the enclosure and the control unit that couples the source of cooling fluid to the enclosure;
wherein the ballast volume is connected to a fill line at room temperature; and
wherein in use the capillary is continuously filled with thermalising fluid during operation of the system.

12. (canceled)

13. A system according to claim 1, including a filter comprising a housing of conductive material, having one end coupled to an inlet capillary and an opposite end coupled to the or a capillary coupled to the enclosure, wherein the housing provides a chamber filled with a sinter filtering element, the filter being operable to reduce or prevent high frequency noise from entering the enclosure through the filling capillary and improve thermalisation of cooling fluid entering the enclosure.

14. A system according to claim 1, comprising first and second sources of cooling fluid, the first source being a source of ³He and the second source being a source of ⁴He, wherein the control unit is configured to control the operation of the first and second sources to supply cooling fluid sequentially or simultaneously.

15. A system according to claim 1, wherein the control unit is operable to control one of:
(i) the amount of cooling fluid in the enclosure;
(ii) the pressure of cooling fluid in the enclosure; and
(iii) the supply of thermalising fluid and pressure to generate at least one layer of thermalising material onto the quantum circuit.

16. (canceled)

17. A system according to claim 15, wherein the control unit is configured to template separate layers of solid thermalising material at the surface of the quantum circuit, said layers being of different thermalising material.

18. A system according to claim 1, comprising at least sensor configured to measure a parameter of the performance of the quantum circuit to obtain a measured quantity, wherein the control unit is configured to control the at least one source of cooling fluid on the basis of the measured quantity by controlling one of the amount and pressure of cooling fluid in the enclosure on the basis of the measured parameter.

19-21. (canceled)

22. A system according to claim 17, comprising:
(i) at least one sensor configured to measure at least one of: noise, decoherence, thermal excitation probability of qubit states, phonons, quasiparticle density, quasiparticle parity fluctuations, losses, thermal population of spins, temperature-dependent superconductor properties, temperature dependent properties of the quantum circuit, qubit relaxation or dephasing times, single or multi qubit gate fidelity, error rate of a logic qubit, algorithm fidelity, quantum gate operation fidelity, and temperature-dependent properties impacting the performance of a quantum computing circuit.

23. (canceled)

24. A system according to claim 1, wherein the control unit is operable to control at least one of:
(i) temperature of the cooling fluid on the basis of determined coherence of the quantum circuit;
(ii) the amount of cooling fluid in the enclosure on the basis of one of measured or and expected power dissipation in the quantum circuit; and
(iii) the pressure of cooling fluid in the enclosure on the basis of one of measured and expected power dissipation in the quantum circuit.

25-26. (canceled)

27. A system according to claim 1, wherein the enclosure is configured to hold a plurality of quantum circuits in a plurality of sub-enclosures, wherein the temperature in each sub-enclosure is controllable one of collectively and individually.

28-31. (canceled)

32. A method of controlling the temperature of a quantum circuit to an operating temperature below 100 mK, in a system including:
an enclosure comprising enclosure walls made of temperature conductive material;
a volume of porous media made of thermally conductive material disposed in the enclosure and thermally coupled to at least a part of the enclosure walls;
a substrate for holding a quantum circuit in the enclosure;
at least one source of cooling fluid;
at least one port in the enclosure directly coupled to the source of cooling fluid; and
a control unit coupled to the at least one source of cooling fluid;
the method comprising the steps of operating the control unit to fill the enclosure with cooling fluid to cool the quantum circuit and/or its environment, and to control the supply of cooling fluid to the chamber so as to control a degree of cooling provided by the thermalising fluid in the enclosure and thereby the amount of cooling provided to the quantum circuit, said control permitting to tune the performance of the quantum circuit.

33. (canceled)

34. A method according to claim 32, wherein the system comprises first and second sources of cooling fluid, the first source being a source of ³He and the second source being a source of ⁴He, the method including the step of the control unit operating or enabling the operation of the first and second sources to supply cooling fluid one of sequentially and simultaneously; and
comprising the step of measuring the at least one parameter indicative of the performance of the quantum circuit, and controlling the at least one supply of cooling fluid on the basis of the performance measure by controlling one of the amount and pressure of cooling fluid in the enclosure on the basis of the measured parameter.

35. (canceled)

36. A method according to claim 32, comprising operating the control unit to control the supply of thermalising fluid and pressure to generate a plurality of layers of thermalising material onto the quantum circuit.

37. A method according to claim 36, comprising operating the control unit to deposit separate layers of solid thermalising material at the surface of the quantum circuit.

38-43. (canceled)

44. A method according to claim 32, including the step of controlling temperature to a predetermined level on the basis of determined coherence of the quantum circuit.

45-47. (canceled)

48. A method according to claim 32, comprising the step of controlling at least one of the amount and the pressure of cooling fluid in the enclosure on the basis of at least one of measured and expected power dissipation in the quantum circuit.

49. A method according to claim 32, comprising the step of holding a plurality of quantum circuits in a plurality of sub-enclosures, and controlling the temperature of the cooling fluid in each sub-enclosure one of collectively and individually.

50. A method according to claim 37, wherein said layers are of different thermalising materials.
